(19) United States
(12) Patent Application Publication
(10) Pub. No.: US 2004/0224292 A1
(43) Pub. Date: Nov. 11, 2004

(54) Method and system for coaching literacy

(76) Inventor: Gene Steve Fazio, Tempe, AZ (US)

Correspondence Address: LEWIS AND ROCA, LLP, 40 N. CENTRAL AVE., PHOENIX, AZ, 85004, US

(21) Appl. No.: 10/841,392

(22) Filed: May 7, 2004

Related U.S. Application Data
(60) Provisional application No. 60/469,535, filed on May 9, 2003.

(51) Int. Cl. G09B 19/00; G09B 1/00; G11C 8/00

(52) U.S. Cl. 434/156; 434/167

(57) ABSTRACT

There is provided a method and system designed to (1) coach school children who have responded poorly to group writing instruction to obtain mastery in writing, and (2) allow peer students and parents, even with minimal training, to educate students who are failing in literacy. The disclosed methodology enables tutors and parents to teach how to write well without having to explain how to write well.

### CROSS REFERENCES TO RELATED APPLICATIONS

This application claims the full benefit and priority of U.S. Provisional Application Ser. No. 60/469,535, filed on May 9, 2003, the disclosure of which is fully incorporated herein for all purposes.

### STATEMENT REGARDING FEDERALLY SPONSORED RESEARCH OR DEVELOPMENT

Not applicable.

### NOTICE OF INCLUDED COPYRIGHTED MATERIAL

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. All trademarks and service marks identified herein are owned by the applicant.

### BACKGROUND OF THE INVENTION

1. Field of the Invention

The present invention relates generally to methods and materials for tutors to utilize in educating students (or tutees) in writing. More particularly, the present invention relates to a person-to-person method for coaching writing wherein tutees learn content without verbal explanations, and their responses become the content for instruction.

2. Description of the Related Art

Various methods and devices are available for teaching writing in schools. These methods usually involve group instruction with some form of verbal explanation offered by a teacher to present information about methods, rules, and/or processes for writing. The students receiving the verbal instructions are required to attend to the teacher's spoken explanations, and then incorporate the concepts being verbally described into a learning taxonomy. Students are expected to take notes, interact by asking questions, or otherwise prompt the teacher for further clarification when the student is unable to comprehend the subject of the lesson. Unfortunately, verbal explanations or lectures must be understood to be effective. Various sources of information, including testing results, media information, and educational surveys indicate that many students are reading and writing below grade level. This is one indication that students are not comprehending the above mentioned modes of instruction.

Workbook instruction has also been used as a technique to instruct students on reading and writing. In workbook instruction, students are presented with handout materials either in loose-leaf or booklet form and expected to complete assignments that address a particular learning goal. Likewise, computer-driven applications may implement the workbook paradigm in a paperless manner. However, as a prerequisite to completing conventional assignments in a workbook or in a computer program, the students need to have first received an effective verbal presentation regarding the subject being addressed in the assignment, and instructions on how to complete the assigned task. For students that experience difficulty comprehending the teacher's orally delivered explanation and instructions, workbook or computer assignments are an ineffective means to acquire new writing abilities.

Likewise, because of the concern or stigma associated with asking for repeated clarification in a classroom setting, many students are chilled from asking the teacher to repeat or reword a verbal clarification. Students often tease or otherwise criticize students who cannot keep up with the other students being lectured in class. Students who struggle to maintain the group pace are further hampered by impaired self-esteem and the trauma that comes along with many of the cruel labels that can be attached by other students or even educators.

While success in learning is one important means to repair damage to a student's self-esteem and restore confidence, achieving learning goals requires a different approach than those currently in use today. Effectively, the commonly used teaching methods for classroom instruction do not provide adequate instruction for students failing in writing competency. As a result, having tutors merely adapt oral presentations to one-on-one situations has been ineffective in teaching all students how to read and write effectively, especially those students that experience learning challenges.

As background for the present invention, Edward Tolle, author of the bestseller The Power of Now, has presented ideas about three levels of consciousness and thought in his lecture “The Realization of Being,” which is available from the company Sounds True, the entire content of which is hereby incorporated by reference for all purposes.

The first level of consciousness according to Tolle is consciousness without thought. A cat watching a mouse hole is conscious, but conceptual thought is not present because a cat does not have language. The consciousness of a cat is below thought.

Tolle explains that the second level of consciousness is consciousness with thought. A human being has and uses language, thus making conceptual thought possible. A human being's consciousness in a state of thought is superior to the cat's consciousness of no thought.

Tolle's third level of consciousness is “consciousness beyond thought.” He says that human beings can operate in a state of consciousness of no thought, and when this state is beyond thought, it is superior to a state of thought. A clear example of this is a person typing. A skilled typist can hit the correct keys on the keyboard without thinking about hitting the keys. Actions are automatic. Thought in this case would block the natural flow of movements. That is, a typist thinking about which key to strike would have paralysis by analysis. As a result, this state of beyond thought is superior to the state of thought.

Tolle's concepts challenge educators. Human beings can operate in a state of consciousness of no thought, and this state is superior to a state of thought. This idea may seem unusual and hard to understand. However, there are practical examples in the areas of football and theater. During the 2003 Rose Bowl, one commentator noted that a goal of the USC defense would be to get the Michigan quarterback to start thinking. This is because “when you analyze, you paralyze.” Thought with language interrupts the natural flow of players' movements. When an athlete is in the zone, thought with language is not present and does not block the natural flow of movements. In the words of Tolle, “Animals because they have no language, do not have thoughts blocking the totality moving through them. A bird does not decide to fly to the next branch. It just does.” In other words, a bird does not have to deal with “paralysis by analysis” because of thought with language.

Another example is theater. When actors think about what they are doing and listen to their inner dialogue while on stage, they prevent themselves from being fully self-expressed. In contrast, they strive to “be in the moment,” and this state occurs in the absence of thought with language. In both football and theatre, players and actors do not expand their capacities and acquire new abilities to the level of mastery through learning lessons and understanding explanations. Knowing more will get an athlete and actor only so far. It is through doing practices over and over and getting coaching on the spot that an athlete and actor can achieve a level of mastery that results in their being able to do what they do automatically in a state of beyond thought without even having to think.

To summarize, a human being operating in a state of no thought is not the same as a cat's state of no thought. A cat's state of no thought, is a state of pre-thought and thus below thought. A human being operating at a state of consciousness of no thought is operating at a level beyond thought. Tolle states, “When a human being returns to the state of no thought after operating at a level of thought, it has an added dimension and depth of incredible knowing to it, which animals do not have because they are in the original state of no thought . . . . In the state of beyond thought, thought can be used, but it is no longer controlling the thinker.” Put another way, thought can be used in the complete absence of language. Thought is non-verbal.

Other examples exist of people acquiring such a high level mastery that they are able to do something automatically without needing the conscious mind to understand or comprehend a task at hand. In the movie The Karate Kid, Danielson waxed cars, sanded floors, painted fences, and painted a house. Through these actions that did not require verbal explanations or did not require him to use his conscious mind to understand or comprehend discrete skills, he acquired new karate abilities and operated at a level of consciousness of the third level, beyond thought. Current instruction methodologies do not recognize these important principles, and therefore there exists a need to integrate these principles into a new instruction methodology.

What is needed is a new methodology of instruction for those who are performing below grade level in writing, giving them the opportunity to have success in place of failure. What is also needed is an interactive learning format that enables students to acquire new writing abilities even though those students have difficulty comprehending verbally delivered lectures on writing or textbook explanations for how to write.

What is also needed is teaching materials and methodologies that appear easy to use for non-teachers, laypersons, tutors, and students, and that inspire tutors to motivate students toward the task of overcoming past problems. What is also needed is a method in which more cost-effective lay tutors and parents teach literacy and writing effectively. What is also needed is a learning method that breaks down the complex task of acquiring new writing abilities into component parts. Also what is needed is a method in an interactive learning environment to integrate a tutor's feedback with the tutee's responses without having to rely on verbal explanations. Also, what is needed is a new methodology of instruction that does not require analytical thinking so that those who are performing below grade level in writing and reading can gain more from fifteen hours of instruction in five days than they can from fifteen hours of instruction over five weeks. What is further needed is a methodology that does not rely on verbal explanations because training tutors to use verbal explanations requires extensive training, and students with weak academic backgrounds can have difficulty understanding verbal explanations that were designed to prepare them to write.

### SUMMARY OF THE INVENTION

In view of the foregoing, it is an object of the present invention to improve various problems associated with the prior art. To this end, an object of the invention is to provide a method and a process that does not resort to verbal explanations so that a teacher, tutor, layperson, or parent with minimal training can be successful in tutoring writing, and at-risk students can break their cycle of failure in reading and writing. Because the present invention enables tutees to learn content without verbal explanation, tutees can complete the equivalent of a one-credit composition course on five contiguous days.

Another object of this invention is to provide learning-by-doing instruction that does not require analytical thought and language, and is therefore referred to as Non-Verbal Knowing^{SM}. By eliminating verbal instructions prior to students' writing, the teacher eliminates the problem of students having verbal explanations to ponder. Unnecessary thinking unfortunately sometimes results in paralysis by analysis. By not resorting to verbal explanations, the teacher can cause students to acquire, for example, the ability to use naturally and automatically embedded participial phrases to show what emotion a person is feeling. From the beginning, the student can be operating at Tolle's third level of consciousness, beyond thought.

Through the method of the present invention, students simply learn to write embedded participial phrases by writing embedded participial phrases. For example, students learn by performing guided practices that lead them into writing embedded participial phrases to show what emotion a person is feeling. What makes this process different is that to complete these practices, students merely follow some easy steps. They do not to need to understand or analyze instructions prior to doing the practices.

This is possible because the present invention enables tutors to teach how to write well without having to explain how to write well. The following description demonstrates a process in which this methodology can be effectively applied in one-on-one instruction scenarios. All instruction begins with the tutee (“student” and “tutee” are used interchangeably herein) completing a learning aid in the form of a specially formatted template. The tutee completes the learning aid by following directions supplied by the learning aid without having to first understand explanations on the subject matter being taught in the learning aid. By completing the specially-formatted learning aid, the tutee learns by example, not by being told verbally about the subject of the lesson. The tutor (“tutor,” “teacher,” “layperson,” and “parent” are used interchangeably herein) observes the tutee completing a template with words, phrases, sentence fragments, or sentences. The tutor makes a positive evaluation of the tutee's correct completions with positive comments reinforcing correct responses. The tutor responds to inappropriate words, phrases, or sentences by making corrections or giving examples such as writing an appropriate word or phrase in places where the tutee has not submitted answers or has supplied incorrect answers to complete the template. The tutee is then asked to give examples in place of the ones inserted by the tutor. The tutor observes each new attempt of the tutee, evaluates and responds to it appropriately as before and thus guides the tutee ever closer to being successful. The responses of the tutee, therefore, becomes content for the instruction, and the lesson does not need to involve verbal explanations to explain why something was wrong. The process just described is called “You Practice. I Coach. You Learn.”™^{SM} In this way, the tutor can direct and guide the tutee as to what to write and what not to write without resorting to verbal explanations. The method of the present invention that enables teaching how to write well without using verbal explanations results in non-verbal knowing, which makes it possible for minimally trained tutors to have a substantial impact on a tutee's educational success.

Not resorting to verbal explanations makes this invention different from any other method of teaching writing. The best way to prepare students to be good writers is to have them write. This concept of “learning by doing” and having students spend most of their time “on task” has been around since the days of the famous educator John Dewey. However, teaching writing in the classroom calls for teachers to define, explain, or discuss methods or processes to prepare students for writing. Unfortunately, when the teacher is talking, the students are not writing. In addition, knowing “that” information and having the ability to perform writing tasks are different.

By not resorting to verbal explanations, this invention does not spend time preparing students in order to perform writing tasks. All tutees are given before writing are some easy steps to follow. Instead of studying lessons, they do practices. Again, the practices are so simple that they do not require students to understand or figure out anything before doing them because all that is required is that tutees just follow some easy steps.

It is through doing the practices that students acquire new reading and writing abilities in contrast to acquiring new abilities by knowing rules or procedures. For example, students will be able to recognize participial phrases and know how to use embedded participial phrases to show what emotion a person is feeling without needing to study lessons or understand teacher discussions and explanations about participial phrases.

By not resorting to verbal explanations, this methodology creates another path to literacy for the academic have-nots. The more a person knows, the easier it is for that person to know more. Because verbal explanations are not used, those students with poor academic backgrounds will not be at a disadvantage from not understanding.

It is another object of the invention to provide specially formatted learning templates to enhance student learning with nonverbal instruction. Each learning template seeks to teach a specific skill to a student, or integrate a collection of previously learned lessons. The learning templates for parts of speech, for example, contain text examples of the lesson to be learned by the tutee, with grammatical elements identified. The templates also provide written directions to follow in completing a series of partially complete sentences. The sentences are composed so that the students can learn by example and fill in the appropriate grammatical elements to complete the exercise. Additional practice to achieve mastery is enhanced by providing more opportunities to practice on example sentences with fewer provided examples.

Yet another object of the present invention is to provide an easily adapted method whereby tutors, even with minimal training, have the opportunity to coach and teach writing successfully with a minimum of training and supervision. The learning templates referred to above are designed to appear “easy” to use. A tutor, parent, and tutee who sees a few pages of the materials containing templates should be able to say mentally, this is “simple.” The simplicity also induces parents to use the materials to help their children; consequently, there is an even greater impact on literacy in the community.

Yet another object of this invention is to enable tutors that are not necessarily trained in teaching to effectively educate students in writing and literacy. This invention provides a key advantage in enabling lay personnel to educate students because schools cannot always afford to have a large number of tutors who are trained teachers. On the other hand, if schools rely on tutors with minimal training, many instructional issues abound. The present invention provides a method and materials that do not require general teaching expertise on the part of the tutors because the disclosed method and materials require tutors to explain how to complete the assignment, not how to write well. The present invention also encourages parents to become active educators for their children, increasing the level of literacy in the community.

Yet another goal of the present invention is to overcome problems of writing programs designed for group instruction so that students who are now failing reading and writing classes can be successful by getting individualized instruction with a methodology that does the following:

(a) Prevents confusing students who have failed by eliminating verbal explanations that require prior knowledge for understanding.

(b) Prevents confusing students who have failed by eliminating composition assignments that do not break an assignment into its component parts and show “how-to” and do not lead students through the step-by-step process of learning “how-to” by completing a series of exercises that result in students knowing “how-to” by doing.

(c) Breaks down complex tasks into component parts. As tutees master the simpler component parts, they are prepared to move to more complex tasks.

(d) By using the method and materials, one can tutor students struggling with writing and/or reading and it can be done in a cost efficient manner.

(e) Appeals to students who have failed a writing or reading course by providing the following:

(1) Step-by-step exercises that provide students with immediate successes. This in turn helps to prevent further emotional insult from continued failures, and as a result, prepares the student to learn by repairing some of the past damage to self-esteem. Because this method is so different, the tutor can help a tutee understand that for many people, writing problems are not internal, but are external, and very likely originated with the method of instruction used to teach them how to write.

(2) Instruction is an interactive process that extracts heavily from words and sentences offered by the tutees, thus giving the tutees the opportunity for offering words commensurate with their own levels of language usage.

(3) Materials that appear “easy” to use. A tutee sees a few pages of the materials and says mentally, this is “simple.” That is exactly the message needing to be conveyed to motivate and inspire the participant toward the task of overcoming past problems and actually learning something that could have been “simple” with one-on-one instruction. The simplicity also induces parents to use the materials for helping their children.

(4) A vocabulary level of the materials that represents an additional safeguard to prevent psychological stress on the user. The words chosen show an appreciation for the older participant whose capabilities exceed those of younger children. To water down the vocabulary level might be construed as demeaning to the intelligence of the older participant. On the other hand, tutors can read exercises and writing models to the younger participants and give them meanings to words that they do not understand. (Of course, this cannot be done in classrooms during group instruction, so in classrooms the vocabulary must be controlled.) As a result, the method of the present invention is designed to teach or enhance reading and writing abilities at any level.

(5) A system that operates at a pace governed by the tutee. Thus, tutees can dwell as long as they wish on a particular exercise before moving to the next one.

(6) A system that physically involves the tutee in the learning process by having the tutee learn by doing as opposed to having the learning process primarily be something mental.

(7) Learning materials that require students to follow simple directions to complete an assignment, rather than requiring the students to understand explanations or instruction from a tutor. The sequence of instruction can be summarized as “You practice” (in which a tutee performs a task) followed by “I coach” (in which the tutor teaches by responding to what the tutee has done) followed by “You learn” (in which the tutee learns “how-to” without the tutor having to explain “how-to”).

It is yet another object of this invention to provide an interactive method and materials for teaching writing specifically in one-on-one situations. This embodiment of the invention is a process that uses original and copyrighted instructional materials that incorporate “You Practice. I Coach. You Learn.”™^{SM} and teaches “how-to” without explaining “how-to,” thus resulting in non-verbal knowing or understanding.

In each lesson progressively presented to a tutee, there is overlapping and building of the elements in each step throughout the process although the goal remains constant. Most steps compliment the preceding ones and continue functioning until the objective is realized. The key is achieving mastery through repetitions and not through understanding explanations.

One embodiment of this methodology is particularly well adapted to one-on-one instruction. Some of the advantages of the one-on-one approach as applied to the present invention comprise the following:

(a) Having students practice and then provide coaching for everything that everyone is doing is impractical with a large group of students. However, in a one-on-one situation “You practice, and I coach” is effective and ideal. In contrast, with group teaching, teachers rely on “lecture, listen, and learn” to reach many students at one time.

(b) In one-on-one instruction, it is possible to focus on the practices that students do because “You practice and I coach” is available and practical. In contrast, with group teaching the focus is on lessons for students to learn through verbal explanations in most cases. Also, this process allows the tutor to provide instruction while the tutee is writing.

(c) In one-on-one situations, it is possible to focus on having students follow directions because mistakes are not a problem. Instead, mistakes are an opportunity to work with students one-on-one and use their responses as the content for instruction. Mistakes are a problem in large classes because a teacher does not have the time to use each student's individual mistakes as content for a lesson. As a result, the focus is on instruction that students follow so that they get it right the first time.

(d) In one-on-one situations, it is possible to focus on responding to what students have done. In group instruction, however, the focus is on presenting information for students to learn before they can complete any practical exercises.

(e) In one-on-one situations, it is possible to focus on instructional content being what the person is saying. Note how this was done in the described instruction with parts of speech. In group instruction, however, the focus is on predetermined subject matter.

(f) In one-on-one situations, it is possible to focus on having students learn by doing practices because of the possibilities for interacting and responding to their responses. In group instruction, the focus is on having students learn to do it right the first time because the teacher does not have time to help each student by responding to each of their responses.

(g) In one-on-one situations, it is possible to focus on having students acquire mastery through repetitions because of the one-on-one time that tutors spend responding to their responses. In group instruction, which focuses on “lecture, listen, and learn,” the focus is understanding through explanations because the teacher cannot be with and respond to each student individually each time they do something.

Again, it is an object of the present invention to provide minimally trained tutors with the opportunity to coach literacy successfully while having a minimum of supervision. The present invention allows tutors and supervisors of tutors to review records relating to the tutee's responses and progress in mastering individual exercises. As a result, a tutor can get help from a supervising teacher to see why a tutee is not able to master a particular exercises by looking at the previous exercise to see if the tutee moved to the next one before mastering the previous one. It is an additional object of the invention to allow the supervisor to help the tutor customize instruction for the tutee based on his or her individual responses.

An additional advantage of the method of the present invention is its similarity to the process that athletes use to master their sport and continually improve. When a quarterback sees defensive players suddenly move up toward the line, he may react and change the play, the field becomes a mental image to the athlete, and multiple actions are taken through processing a single image. Using embedded participial phrases to create multiple actions in one image expands the athletes' vision on the field, similarly to the way embedded participial phrases can be used to show a person's feelings and emotions. That is, two or more actions can be embedded in one image. Because of the method of learning provided through the present invention's approach to non-verbal knowing, athletes achieve literacy skills through the same process they use to strengthen their own athletic prowess, and may benefit on the field from the same learning technique that is strengthened by use of the method of the present invention.

Additional objects and advantages of the invention will be set forth in part in the description that follows, and in part will be obvious from the description, or may be learned by practice of the invention. The objects and advantages of the invention will be realized and attained by means of the elements and combinations particularly pointed out in the appended claim. It is to be understood that both the foregoing general description and the following detailed description are exemplary and explanatory only and are not restrictive of the invention, as claimed. Thus, the present invention comprises a combination of features, steps, and advantages that enable it to overcome various deficiencies of the prior art. The various characteristics described above, as well as other features, will be readily apparent to those skilled in the art upon reading the following detailed description of the preferred embodiments of the invention, and by referring to the accompanying drawings.

### BRIEF DESCRIPTION OF THE DRAWINGS

The invention will now be described by way of example with reference to the accompanying drawings in which:

FIG. 1 is an illustration of one type of learning template used in the present invention;

FIG. 2 is a flowchart describing one embodiment of a teaching method used in the present invention;

FIG. 3 is one embodiment of the present invention as implemented in a computer-based environment;

FIG. 4 is another embodiment the present invention as implemented in a computer-based environment involving a computer or wireless network;

FIG. 5 is an exemplary illustration of the learning template from FIG. 1 where a hypothetical tutee and tutor had completed entries;

FIG. 6 is an exemplary illustration of a learning template for introducing concepts relating to participial phrases;

FIG. 7 is an exemplary illustration of a learning template for teaching concepts relating to expanding participial phrases;

FIG. 8 is an exemplary illustration of a learning template for teaching about the question “why” and how it relates to participial phrases;

FIG. 9 is an exemplary illustration of a learning template for teaching the concept of changing reasons into participial phrases that answer “why”;

FIG. 10 is an exemplary illustration of a learning template for teaching about participial phrases through completing partially complete sentences;

FIG. 11 is an exemplary illustration of a learning template for teaching about participial phrases through practicing writing a tutee's own sentences;

FIG. 12 is an exemplary illustration of a learning template demonstrating how explanations when they do come never teach, but make students aware of what they have already learned through doing a practice. In this case, participial phrases create two actions in one image;

FIG. 13 is an exemplary illustration of a learning template continuing the lesson regarding participial phrases where examples of showing a person feeling an emotion are practiced by the tutee;

FIG. 14 is an exemplary illustration of a learning template continuing the lesson regarding participial phrases where more examples of a person feeling emotion are practiced by the tutee;

FIG. 15 is an exemplary illustration of a learning template continuing the lesson regarding participial phrases by changing the name of an emotion into a participial phrase;

FIG. 16 is an exemplary illustration of a learning template continuing the lesson regarding participial phrases by encouraging the tutee to fill in partially complete sentences;

FIG. 17 is an exemplary illustration of a learning template that reinforces the lesson regarding participial phrases by practicing writing a tutee's own sentences;

FIG. 18 is an exemplary illustration of a learning template that teaches about participial phrases and external actions;

FIG. 19 is an exemplary illustration of a learning template where tutees practice writing external actions and participial phrases;

FIG. 20 is an exemplary illustration of a learning template that provides a tutee practice in changing names of emotions into participial phrases that show a person feeling emotion;

FIG. 21 is an exemplary illustration of a learning template that further reinforces the lesson regarding participial phrases by practicing writing a tutee's own sentences;

FIG. 22 is an exemplary illustration of a learning template that addresses subtopic sentences and introduces them to the tutee with exercises;

FIG. 23 is an exemplary illustration of a learning template that continues addressing subtopic sentences and elicits the tutee's responses;

FIG. 24 is an exemplary illustration of a learning template that provides the tutee continued practice in subtopic sentences and then provides a summary and feedback for the tutee;

FIG. 25 is an exemplary illustration of a learning template that provides a tutee practice in writing topic sentences;

FIG. 26 is an exemplary illustration of a learning template that provides a tutee additional practice in writing topic sentences and refines certain skills in “impact” and “reasoning”;

FIG. 27 is an exemplary illustration of a learning template that concludes the practice in writing topic sentences and presents the tutee with feedback information;

FIG. 28 is an exemplary illustration of a learning template that encourages a tutee to revise previously written subtopic sentences and provides guidance in performing the task

FIG. 29 is an exemplary illustration of a learning template that provides a tutee additional practice in learning subtopic sentences by providing the tutee's own sentences;

FIG. 30 is an exemplary illustration of a learning template that provides a tutee with simplified “steps-to-follow”-type instructions, and then guides the tutee to provide input in specific locations by referencing blanks to be completed with indicia referred to in the simplified instructions; and,

FIG. 31 is an exemplary illustration of a learning template that provides a tutee an athletic paradigm to follow in learning participial phrases.

### DETAILED DESCRIPTION

Reference will now be made in detail to exemplary embodiments of the invention, examples of which are illustrated in the accompanying drawings. Wherever possible, the same reference numbers will be used throughout the drawings to refer to the same or like parts.

The present invention provides a novel method for teaching writing to tutees by the presentation of a learning template to a tutee, directions that tell the tutee how to complete the template, opportunity for the tutee to complete the template by filling in blank areas that are patterned on one or more examples, and then written and/or verbal feedback to the tutee by a tutor. The one-on-one approach coupled with learning through nonverbal practiced examples maximizes the learning potential of students who have difficulty assimilating instructions that are provided verbally.

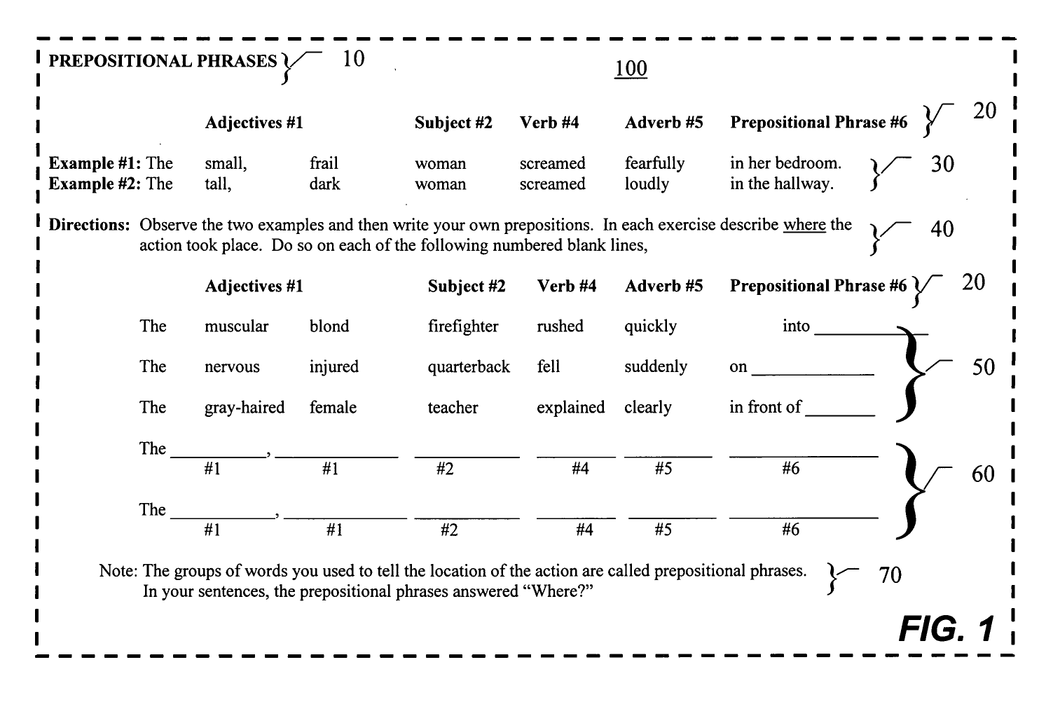

Turning to FIG. 1, one embodiment of a learning template (100) is presented. Many forms of media such as interactive video, computer screens, handheld personal digital assistants (PDA's) or the like may be used to represent the information present on a learning template. In one embodiment of the present invention, learning templates are printed on loose leaf sheets of paper, for possible presentation to tutees separately or in learning directed activity packets. A title (10) is illustrated on the template (100), which represents the general area of educational skills, goals, or concepts addressed by the particular learning template. The text examples (30), separated into component elements and accompanied by component element identifiers (20) illustrate grammatical function of words or phrases in the text examples (30) and provide context for how the elements interrelate. One means to demonstrate the relationship between grammatical function and component elements of sentences is by a matrix or tabular orientation demonstrated in FIG. 1 (20) and (30), where component elements are shown in columns that correspond to a grammatical function. The tutee, in one embodiment of the invention, begins by reading the text examples (30) along with the identifiers (20) and assimilating the basic relationships being illustrated. Written directions such as those illustrated in FIG. 1 (40) are then provided to the tutee, instructing the tutee to follow certain steps to complete the template. As can be appreciated by those of skill in the art, the directions (40) may occur at the top of the template (100) or in an alternate location to enhance clarity. After the instructions, one or more sets of partially complete sentences (50) is presented to the tutee, providing space for the tutee to provide an appropriate response in blank component elements. The tutee is encouraged by the format of the partially complete sentences (50) to mimic the syntax of the examples (30), assisting the tutees in comprehending syntactical and content rules without initial verbal instructions. A tutor can observe a tutee's completion of the partially complete sentences (50) and provide feedback and corrections. More exercise is provided to the tutee by encouraging additional practice in partially complete sentences that have fewer pre-suggested elements (60). By completing the sentences (60), tutees are given more reinforcement in developing their skills, and are simultaneously producing more material so that the tutor can more accurately assess the tutee's progress and provide appropriate feedback. At the end of the template (100), an optional set of prepared feedback statements (70) help summarize the material learned and reinforce in the tutee's mind possible applications of the learned techniques in novel contexts. Additionally, the feedback statements (70) may ask questions for the tutee to consider to further strengthen the learning experience.

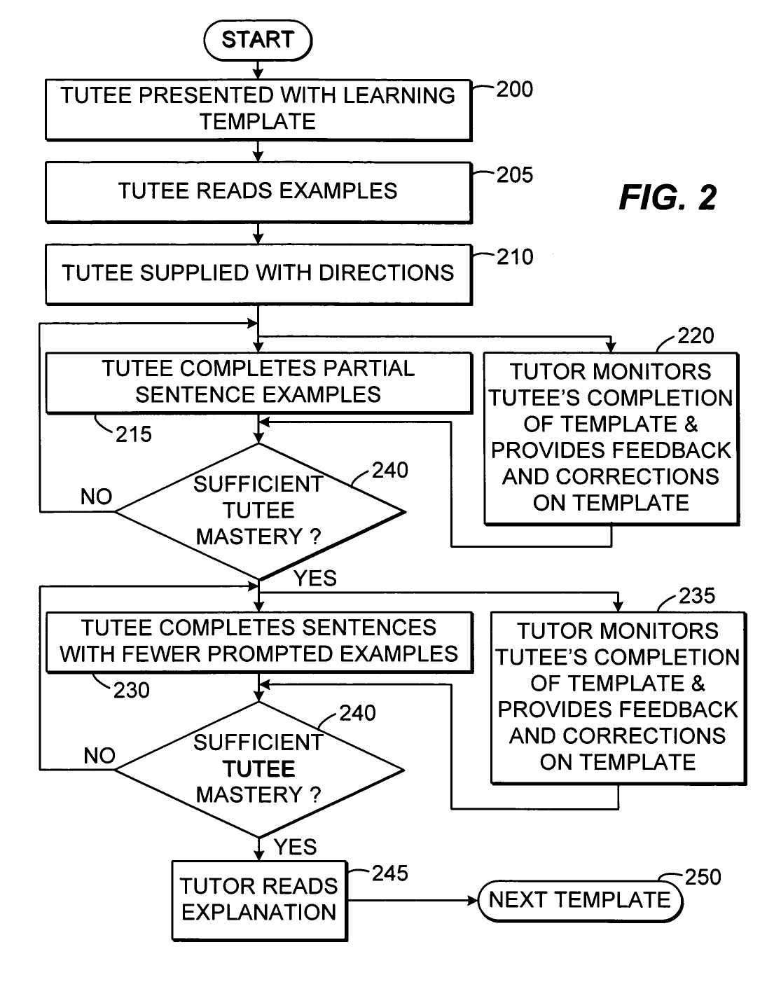

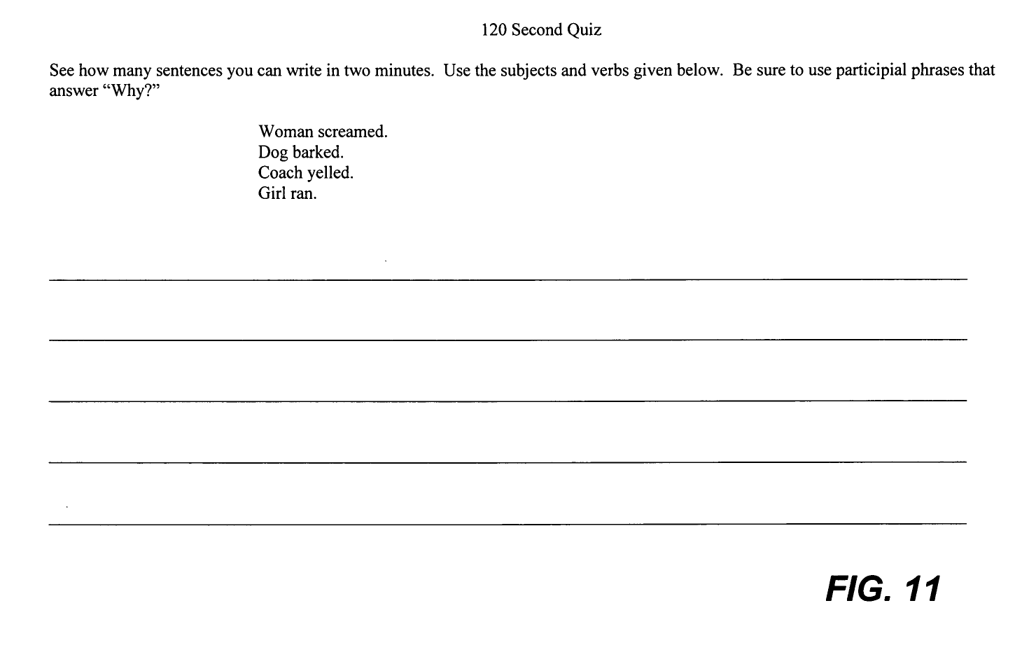

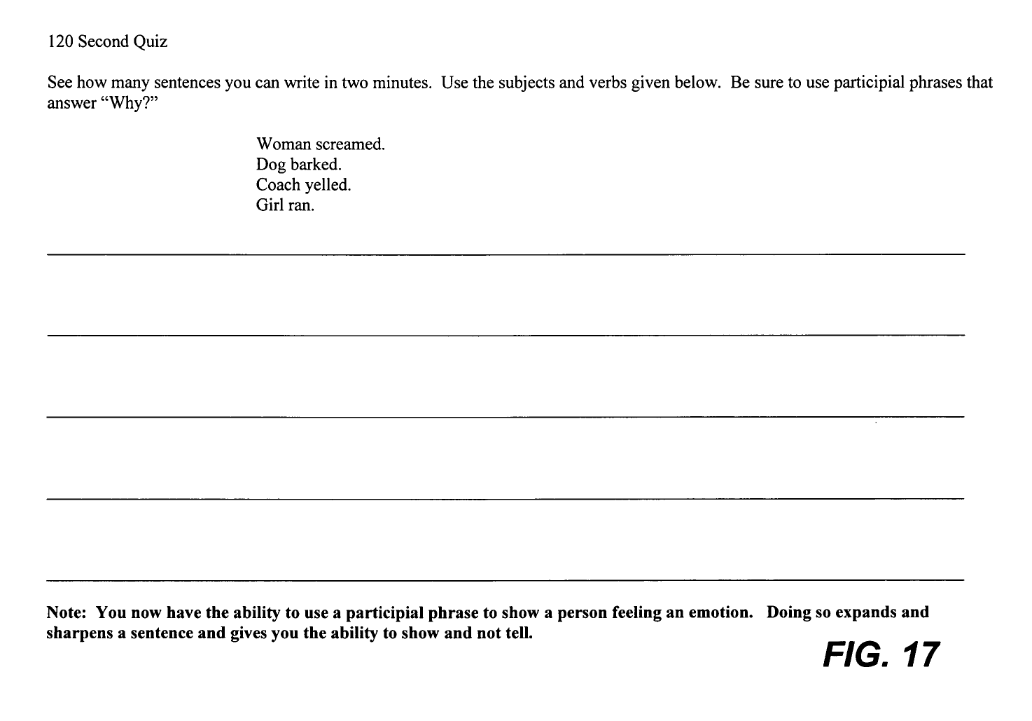

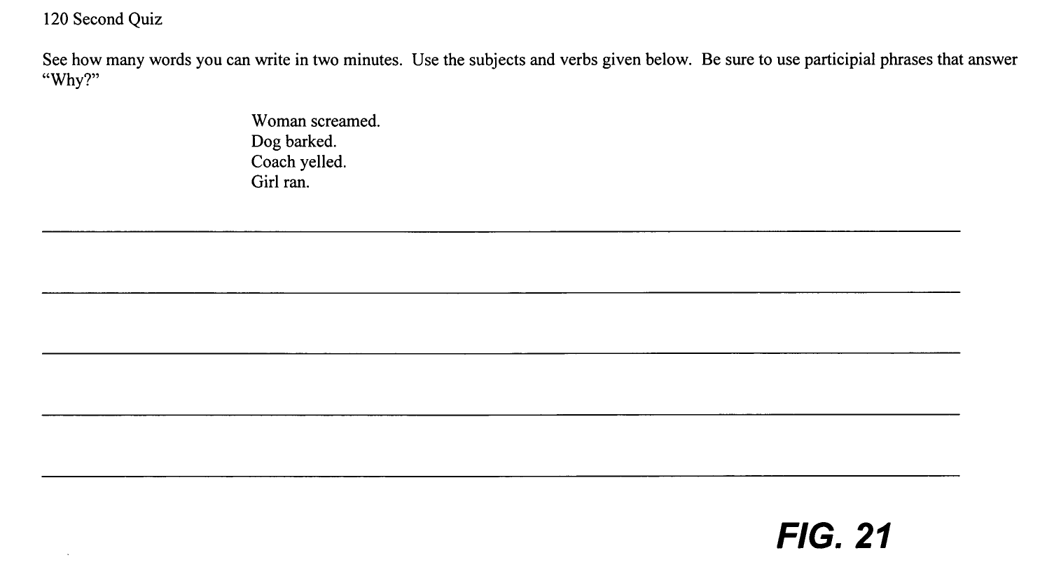

Turning now to FIG. 2., one embodiment of a method for carrying out the present invention is illustrated in flow chart form. The illustrated process is comprised of a series of carefully designed steps in which a language element to be taught is broken down into its component parts, and then presented to a tutee interactively in a primarily non-verbal manner. The method begins with a tutee being presented (200) with a learning template by a tutor. While the preferred embodiment of the present method uses a human tutor that has received minimal training, those of skill in the art recognize that an expert system or other computer-based application can be utilized in the role of a tutor. The tutee then reads text examples (205) on the learning template, along with identifiers describing in individual grammatical elements in the examples. The learning template then provides the tutee written directions (210) on how to complete the template, although those skilled in the art would recognize that this step may be presented at an alternate location in the process, for instance, before the tutee reads the text examples (205). At this point in the illustrated method, an iterative process begins whereby the tutee completes partial sentence examples (215) on the learning template concurrent with the tutor monitoring the tutee's progress (220) towards completing the goal of the template. The tutor also provides feedback to the tutee (220), makes corrections (220), and fills in blanks on the learning template (220) that the tutee was unable to complete. If the tutor decides that the tutee has not achieved a sufficient level of initial mastery in completing the partial sentence examples (225), the tutor continues the process (215) with the student in an interactive feedback and correction cycle. Otherwise, the tutee is encouraged to move on to the next step (230), where the tutee is presented with practice sentences with fewer prepared elements, so that the student has an opportunity to create sentence structures mostly with the tutee's own integrated knowledge. Again, a tutor concurrently monitors the tutee's progress (235), provides feedback to the tutee (235), makes corrections (235), and fills in blanks on the learning template (235) that the tutee was unable to complete. The process continues in an interactive cycle until the tutor has decided that the tutee has sufficiently achieved mastery of the techniques to complete the practice sentences or learning concepts expressed in the learning template (240). The tutor then reads (245) an optional set of feedback statements, explaining what the tutee has learned, and reinforcing the tutee's acquired knowledge. The tutee is then prepared to begin work on the next learning template (250), which may be designed to be more difficult to the tutee than the template just completed. Thus, a tutee can gain increased amounts of learning from completing a series of learning templates, and can further reinforce learned skills through completing additional timed writing exercises such as those shown in FIGS. 11, 17, and 21.

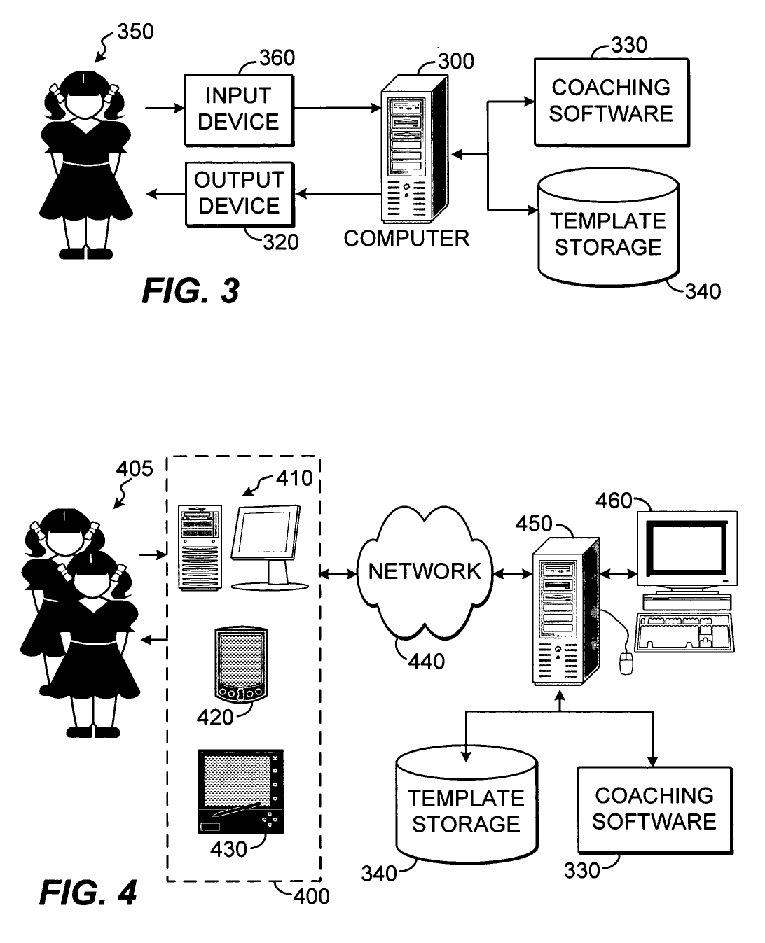

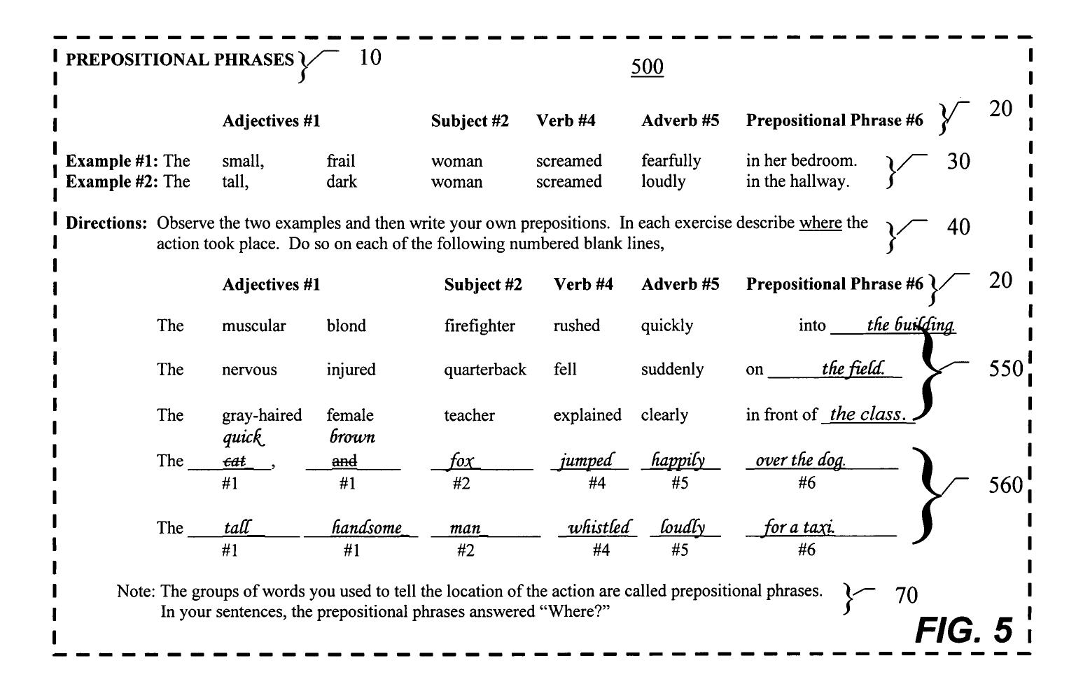

Additional embodiments of the present invention are illustrated in FIG. 3 and FIG. 4. In FIG. 3, the present invention is implemented in a conventional computer environment, such as a personal computer (300), which in the alternative may be a personal digital assistant such as a handheld computing device or a tablet-based computing device. The central processor unit of the computer (300) executes a software program (330) that embodies one aspect of the present invention. The software program (330) instructs the computer (300) to retrieve a computer-based template similar to the illustrated embodiment of FIG. 1 (100) from a connected or integral storage device (340) such as a hard drive. The software (330) and computer (300) then output a computer-based facsimile of the template (100) to an output device or method (320) connected to or integral to the computer (300). Those skilled in the art recognize that the output device or method (320) may comprise any number of computer output devices or techniques such as visual displays via cathode ray tubes, flat panel displays, touch panel displays, pen tablet displays, or the display areas of handheld personal digital assistants (PDAs), and may further comprise audio output, such as synthesized, pre-recorded sounds or synthetic human speech. The software (330) solicits responses from a tutee (350) through the output device (320) and collects the tutee's and tutor's responses though an attached or integral input device or method (360). Those skilled in the art recognize that the input device or method (360) may comprise any number of input means such as keyboard inputs, mouse interface inputs, touch pad responses, or voice recognition methods. Inputs provided by the tutee (350) and optionally by a tutor are processed by the computer (300) and software (330) and stored electronically in memory in the computer (300) or optionally in the storage device (340). One exemplary embodiment of such a software program (330) may comprise a database with pre-designed learning templates implemented as records, and fields within those records representing elements of a template such as illustrated in FIG. 1 (100). In one instance, a template record could have a title field (10), component element identifier fields (20), text example fields (30), written directions fields (40), partially complete sentences fields (50) and (60), and optional feedback statement fields (70), and associated instructions, commands, or scripts to be executed to collect or display the information supplied by the tutor and tutee. Based on the tutee's responses, the software (330) causes the computer (300) to interactively prompt the tutee (350) through the output device (320) to complete additional partially complete sentences (50) or partially complete sentences that have fewer pre-suggested elements (60) by providing inputs through the input device (360). At the option of the tutor, to further strengthen the tutee's practice, the software program (330) and computer (300) may present additional pre-stored partially complete sentences (50) or partially complete sentences that have fewer pre-suggested elements (60) and prompt the tutee to complete the empty fields. After the fields (50) and (60) are completed by the tutee (350) and/or tutor by providing input through devices (360), the responses are stored in the computer's memory (300), in volatile memory, nonvolatile memory, or an attached or integral storage medium (340). The software program (330), at the option of the tutor, can display correct and incorrect answers side by side or vertically opposed on the output device (320), and may provide optional graphical feedback such as highlighting or color schemes showing correct answers in green and incorrect answers in red. The software program (330) optionally may provide instructions to the computer (300) to collect and store statistics based on the tutee's inputs, obtain and store identification information provided for the tutee, and produce reports summarizing a tutee's performance on specific lesson plans and achievement towards learning goals. The software program (330) also may optionally produce reports showing the completed templates appropriately formatted, for instance, for printing and inclusion into a tutee's learning portfolio. Alternatively, in another embodiment, the software program (330) may perform some or all of the functions performed by the tutor, such as reviewing the tutee's inputs, correcting errors made by the tutee, supplying alternative examples, and encouraging the tutee to continue with positive feedback. Optionally, the software program (330) may cause the computer (300) to produce at the output (320) an audible version of the prepared feedback statements (70) that may accompany a template.

Turning now to FIG. 4, the computer system described in regards to FIG. 3 is illustrated as implemented over a computer network to describe an alternate embodiment of the present invention. One or more tutees (405) interact with computer-based input and output devices and methods (400), which may be implemented through a number of approaches, such as conventional computers or remote terminals (410), personal digital assistants (420) such as Palm Pilots, or touch pads or tablet computers (430). The devices (400) execute client software to enable connection of the devices (400) to a network (440) which in turn connects to a server computer (450) that has an optional input/output terminal means such as a monitor and keyboard (460). Those of skill in the art would recognize that the network (440) could comprise either the Internet or a conventional local area network or wide area network such as commonly implemented with Ethernet or Token Ring protocols, or wireless networking approaches such as Bluetooth or 802.11a, 802.11b, or 802.11g WiFi. The server computer (450) executes software (330) that represents an embodiment of the present invention in a manner similar to the method described above in regards to FIG. 3, and template and input information is relayed to tutees (405) through a network architecture (440). The software (330) directs the server computer (450) to retrieve a learning template from a storage medium (340), which may be connected to or integrated in server computer (450). The learning template is transmitted from the computer (450) to input/output devices (400) through the network (440). The input/output devices (400) provide the means for the tutees (405) to perceive the template, and to provide input to the blank fields of the template (50) and (60) (see FIG. 1). The input/output devices (400) then transmit the inputs from tutees (405) to the network (440), after which they are accepted and processed by the server computer (450) and software (330). The software (330) processes the inputs received at the server (450) and in one embodiment, provides output to the terminal (460) for a tutor to review or process at terminal (460). In an alternate embodiment, a tutor reviews or processes tutee's inputs through input/output devices (400). After the fields (50) and (60) are completed by one or more tutees (405) and/or tutor by providing input through input/output devices (400), the responses are relayed through network (440) and stored in the computer's memory (450), in volatile memory, nonvolatile memory, or a storage medium (340). The software program (330), at the option of the tutor, can display correct and incorrect answers side by side or vertically opposed on the input/output devices (400), and may provide optional graphical feedback such as highlighting or color schemes showing correct answers in green and incorrect answers in red. The software program (330) optionally may execute instructions to collect and store statistics based on the tutee's inputs, obtain and store identification information provided for the tutee, and produce reports summarizing a tutee's performance on specific lesson plans and achievement towards learning goals. The software program (330) also may optionally produce reports showing the completed templates appropriately formatted for printing and inclusion into a tutee's learning portfolio. In yet another embodiment, the software (330) is executed by the central processor unit of input/output devices (400), and templates are retrieved from the storage medium (340) through the network (440) or from local memory or storage within input/output devices (400). In another embodiment, the software program (330) may perform some or all of the functions performed by the tutor, such as reviewing tutees' inputs, correcting errors made by tutees, supplying alternative examples, and encouraging tutees to continue with positive feedback. Optionally, the software program (330) may cause the computer (300) to produce at the input/outputs (400) an audible version of the prepared feedback statements (70) that may accompany a template.

As an illustration of one embodiment of the above described invention, FIG. 5 shows one hypothetical example (500) of the learning template in FIG. 1 (100) as filled in by a hypothetical tutor and tutee. The template could have been completed by any of the aforementioned methods, for instance on paper or through a computer-based interface. A tutee begins by reviewing the title (10), component element identifiers (20), and text examples, (30) and then reads the directions (40). While the parts of speech in the text examples (30) are identified by the component element identifiers (20), they are not necessarily defined, explained, or described in the directions. The directions instruct the tutee on how to complete the empty spaces on the template. Using the nonverbal clues provided by the text examples (30) and component element identifiers (20), the tutee then attempts to complete the partially complete sentences (550), and does so by filling in the first space with the words “the building” and the last space “the class.” The tutee is unable to fill in the second space, so the tutor places a suggested solution “the field” into the second space. The tutor provides positive feedback to the tutee, and after recognizing the tutee is ready to continue, encourages the tutee to complete the partially complete sentences that have fewer pre-suggested elements (560). The tutee fills in the spaces of the first line of (560), with the words “cat and fox jumped happily over the dog.” Seeing the tutee's error, the tutor corrects the first two words by writing in other word examples in the first two spaces “quick” and “brown” above the tutee's entries as illustrated on the first line of (560). With the tutor's example encouragement but without any necessary explanation, the tutee grasps the concept, and writes into the spaces of the second line of (560), “tall handsome man whistled loudly for a taxi.” If necessary, the tutee is encouraged by the tutor to write other examples (not shown). Having decided the tutee is ready to proceed to the next template in the lesson series, the tutor then reads the prepared feedback statements (70) to the tutee to reinforce what the tutee has just learned nonverbally.

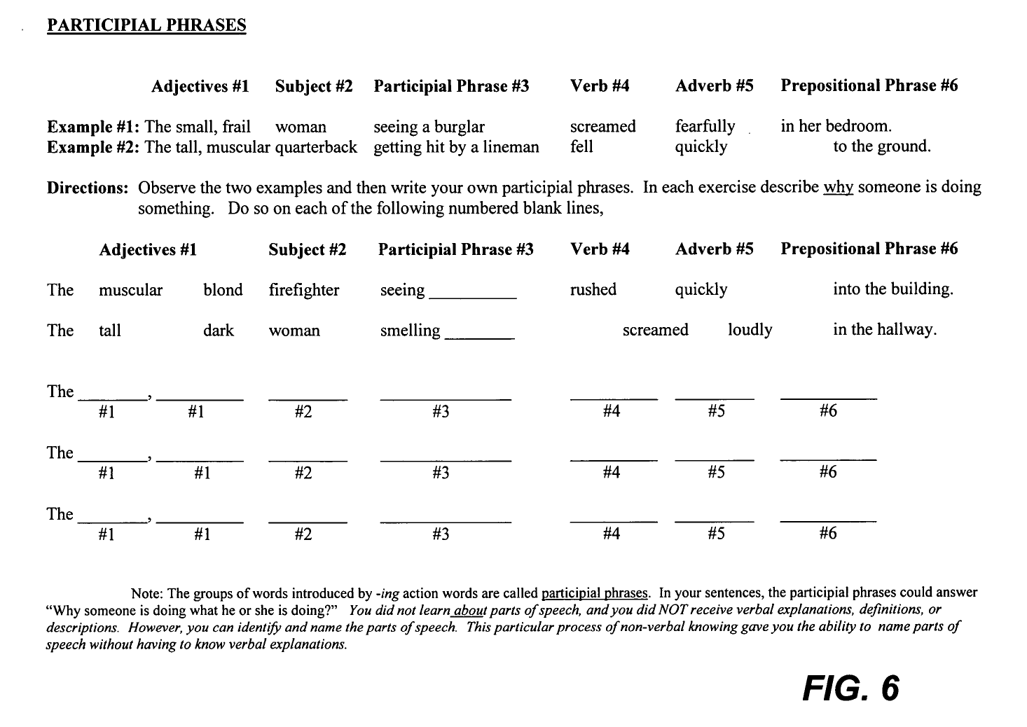

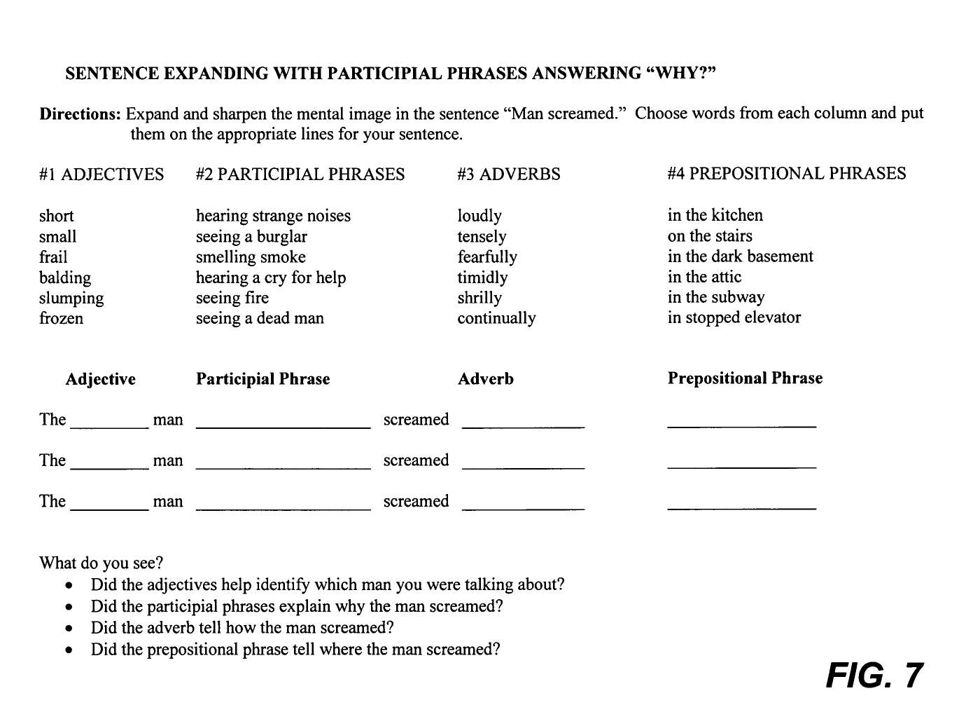

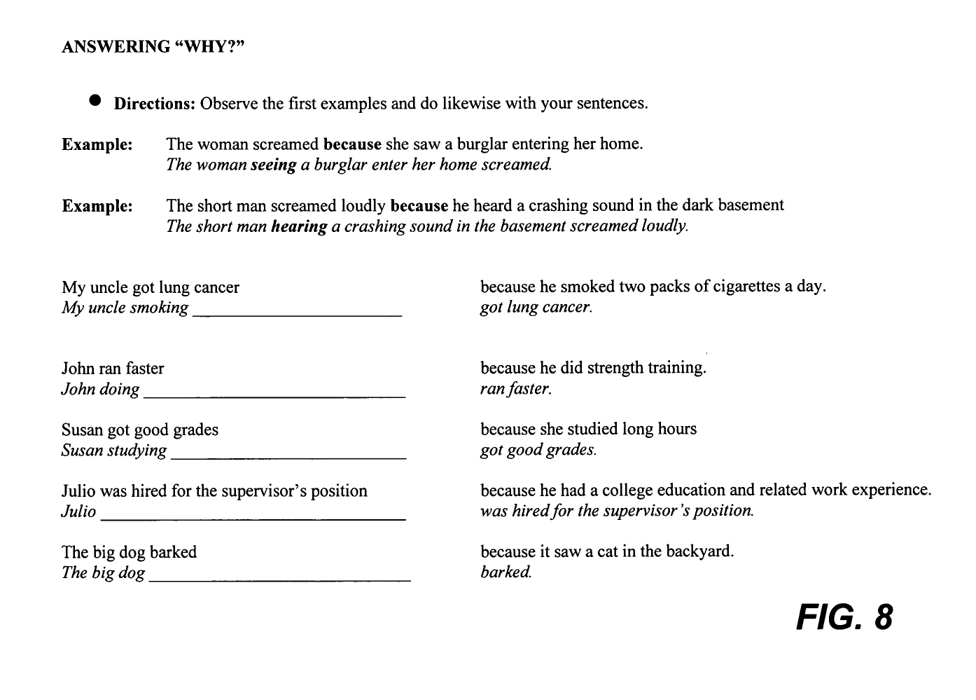

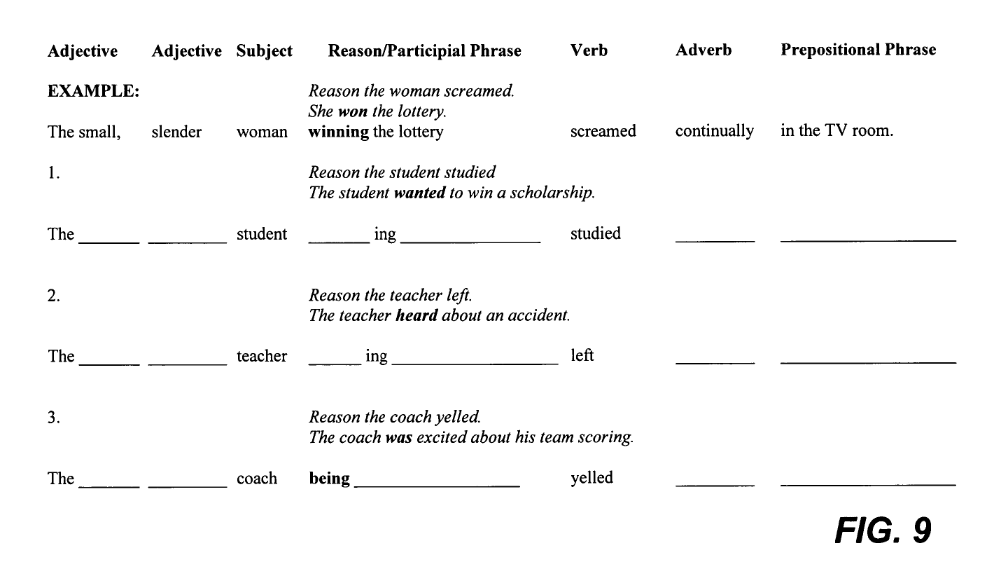

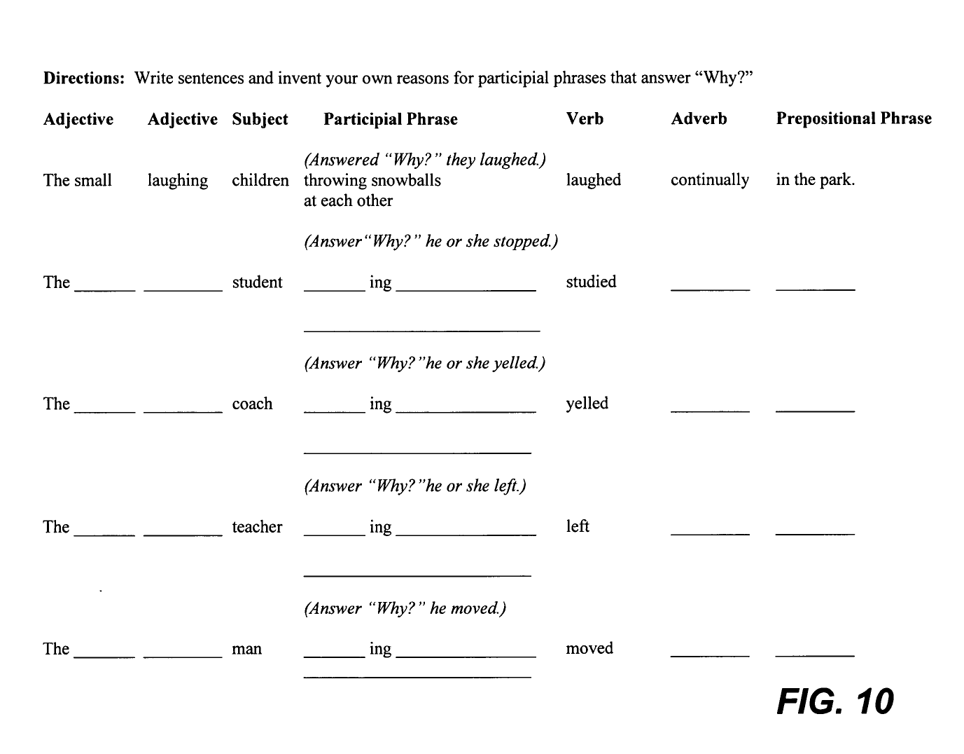

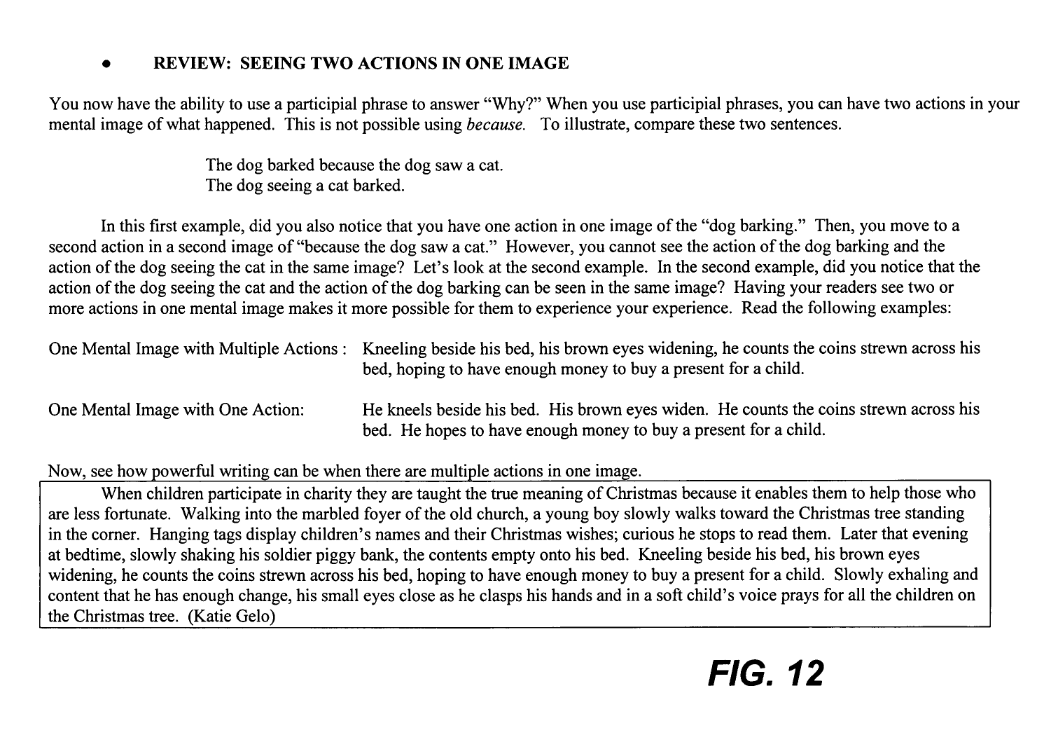

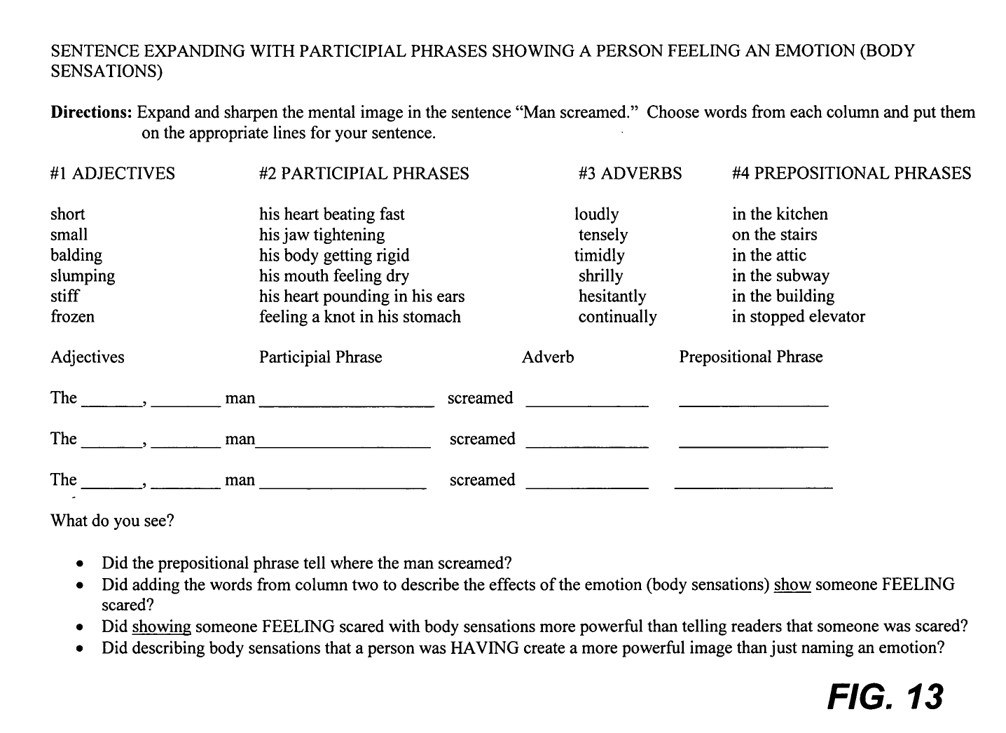

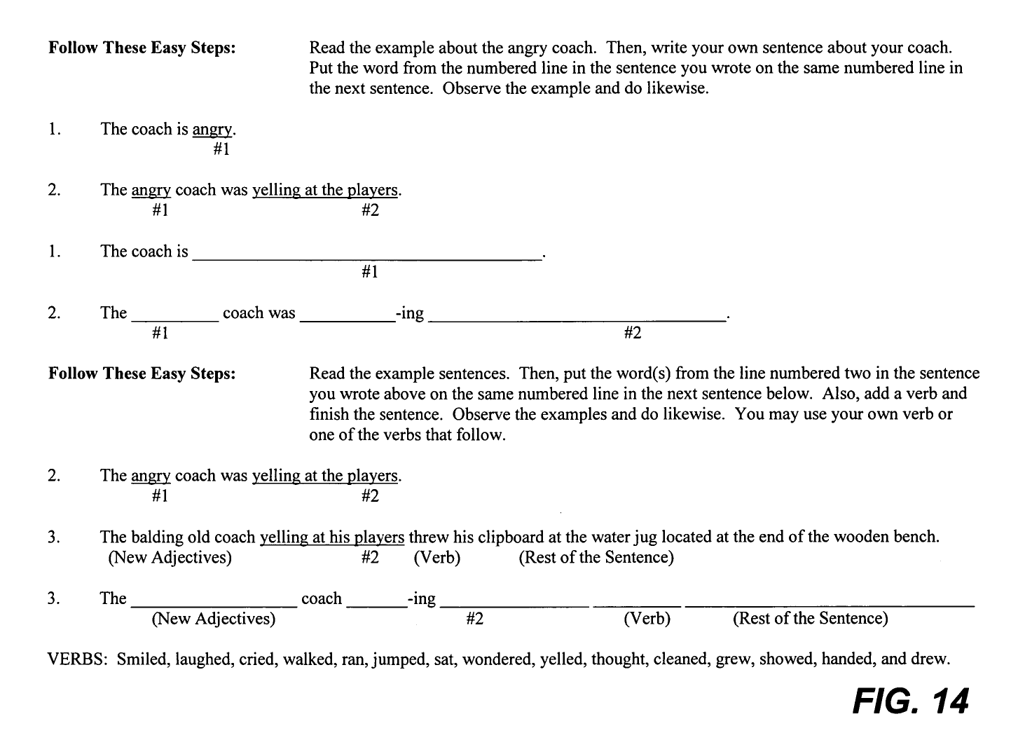

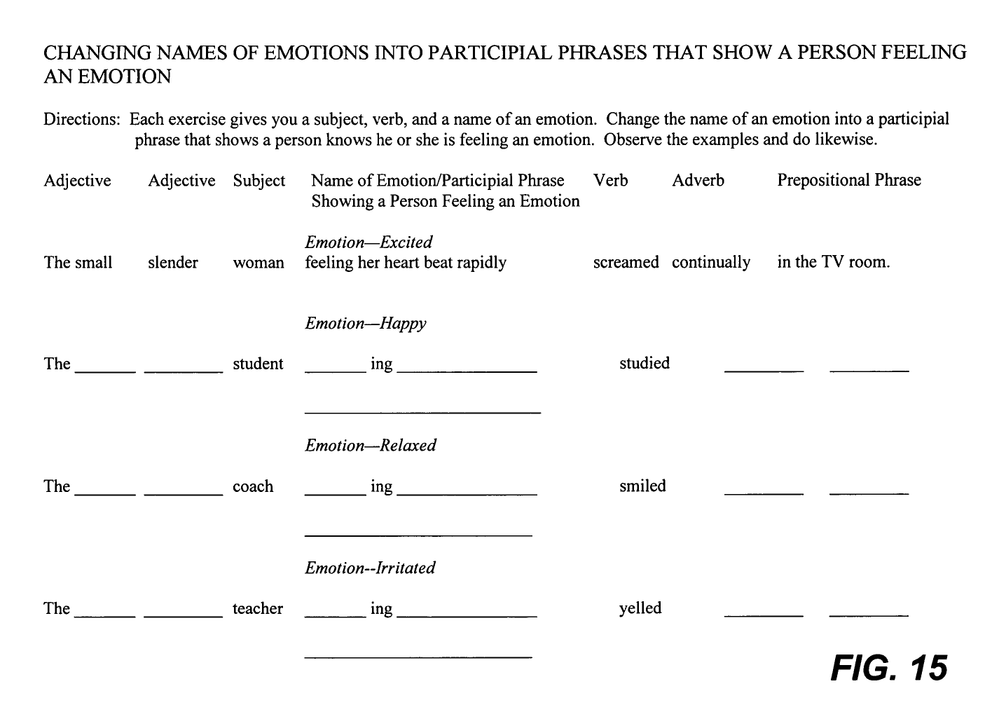

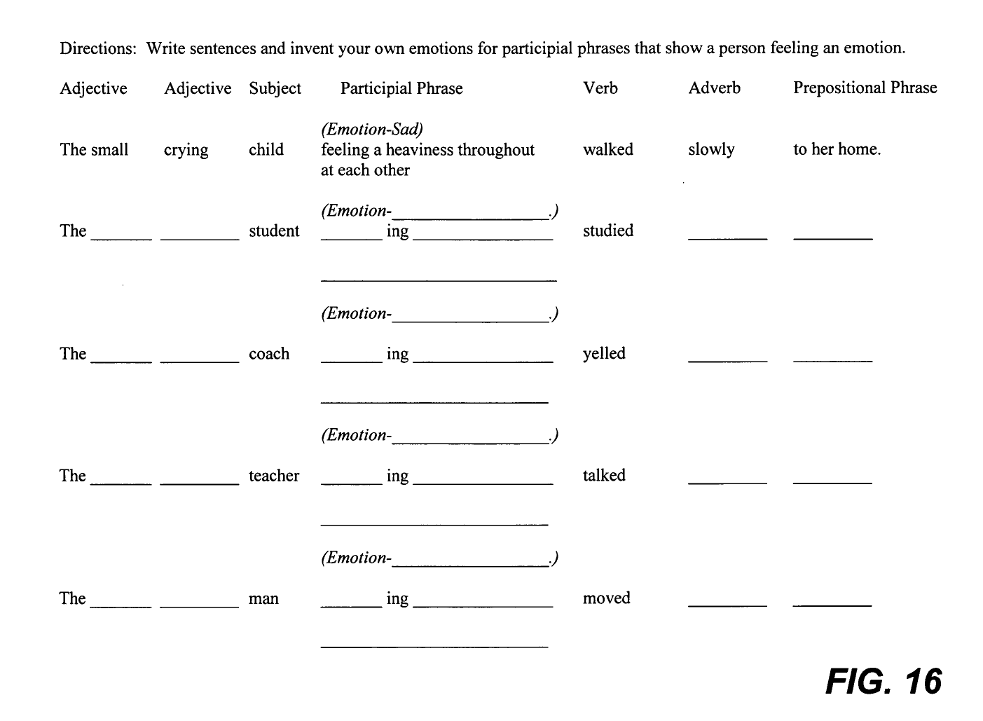

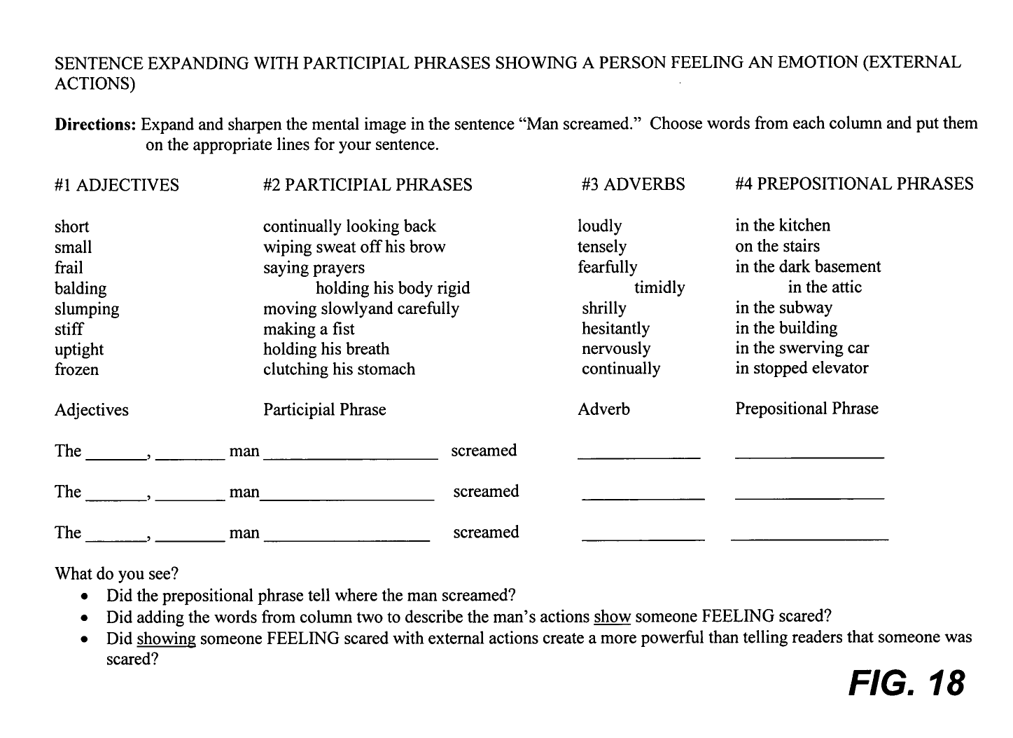

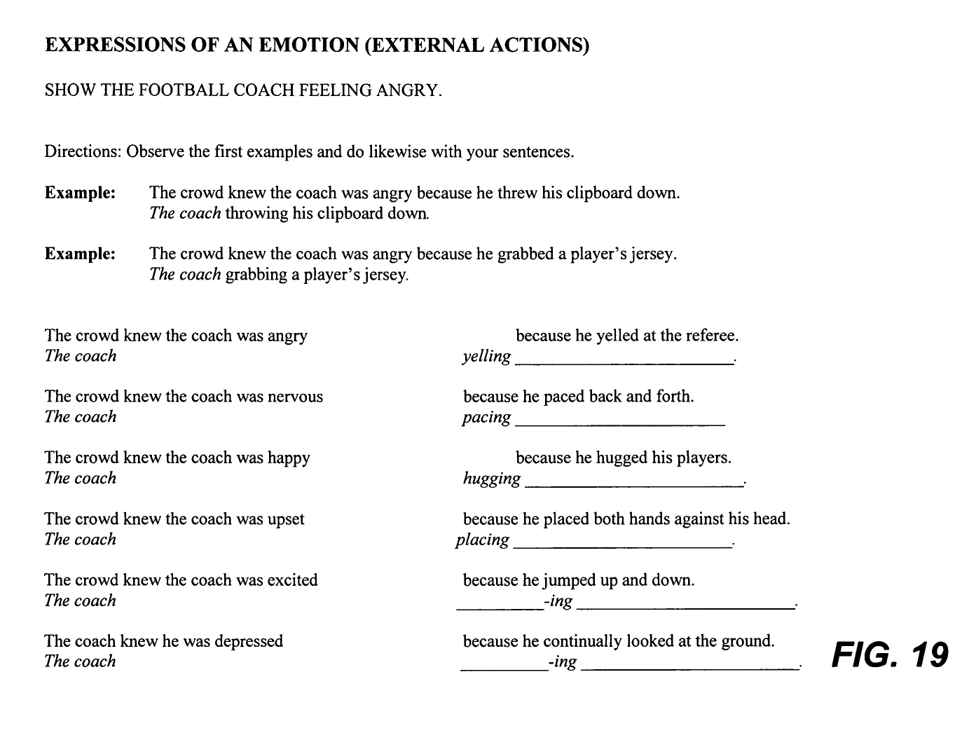

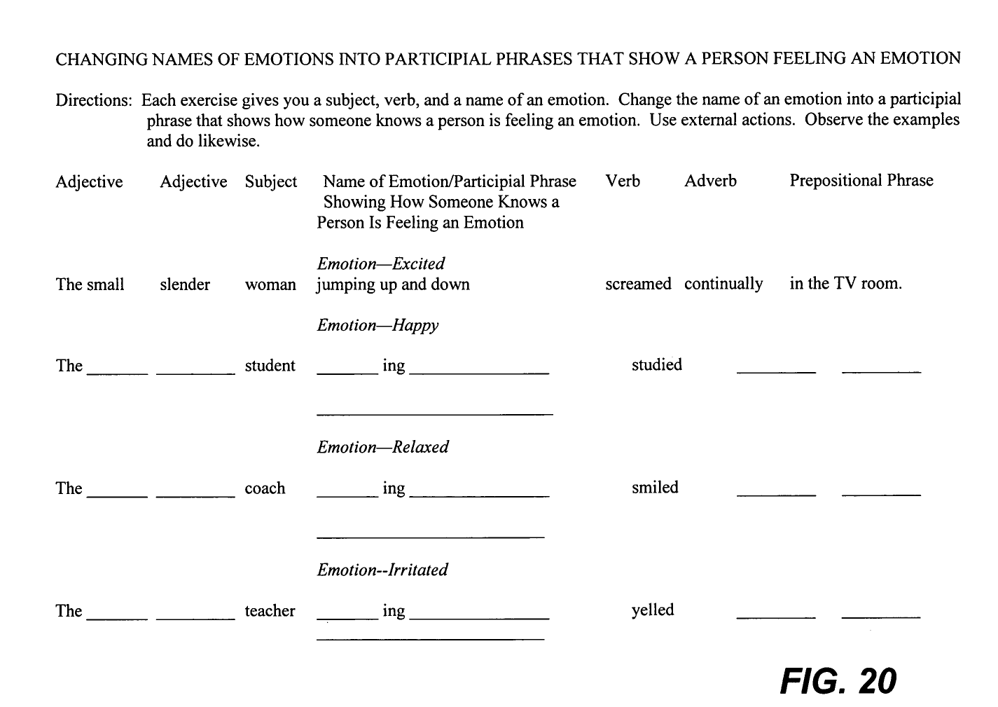

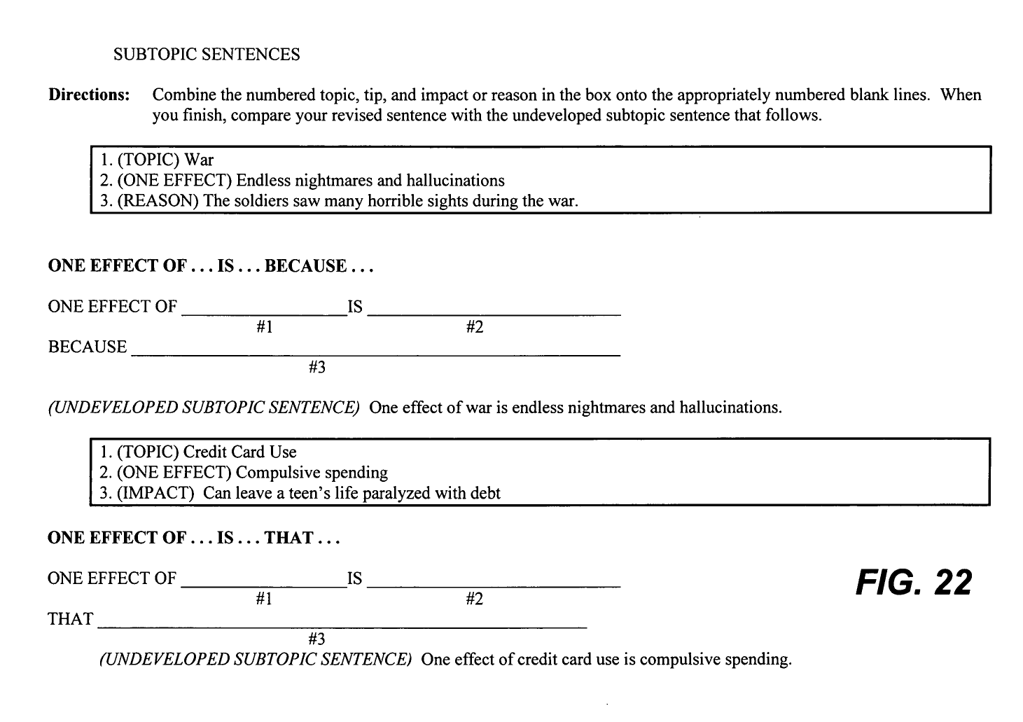

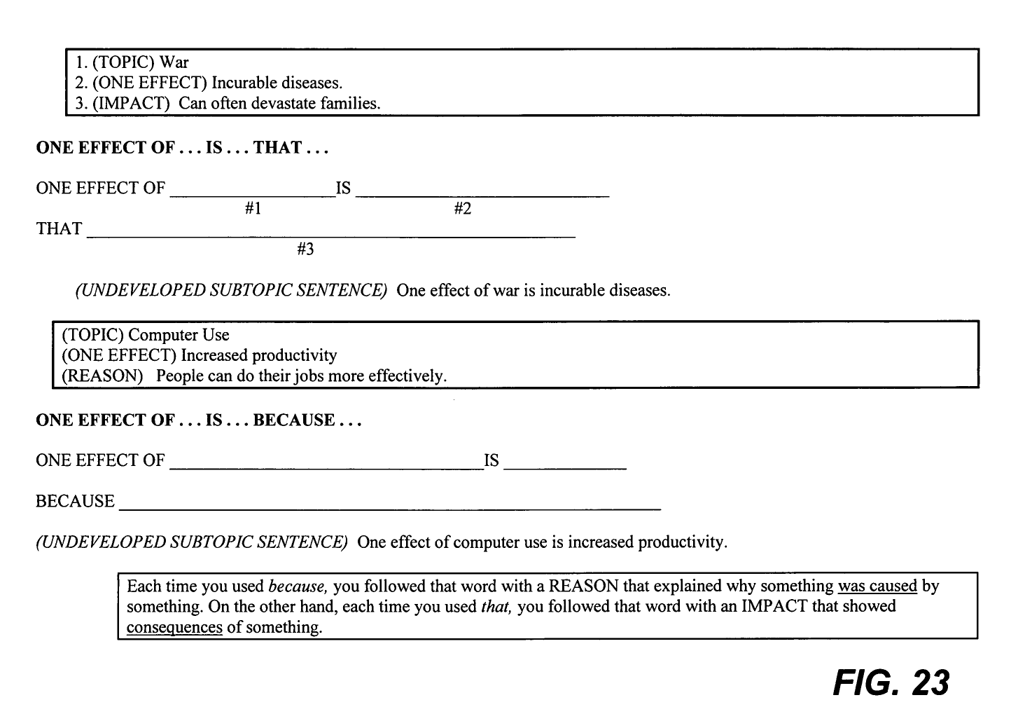

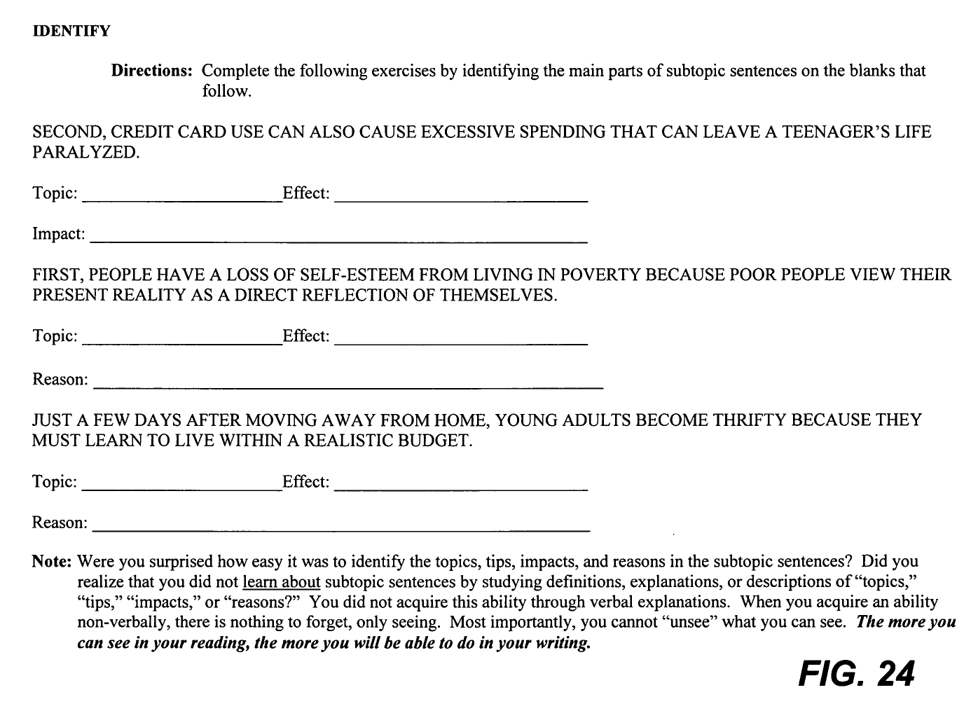

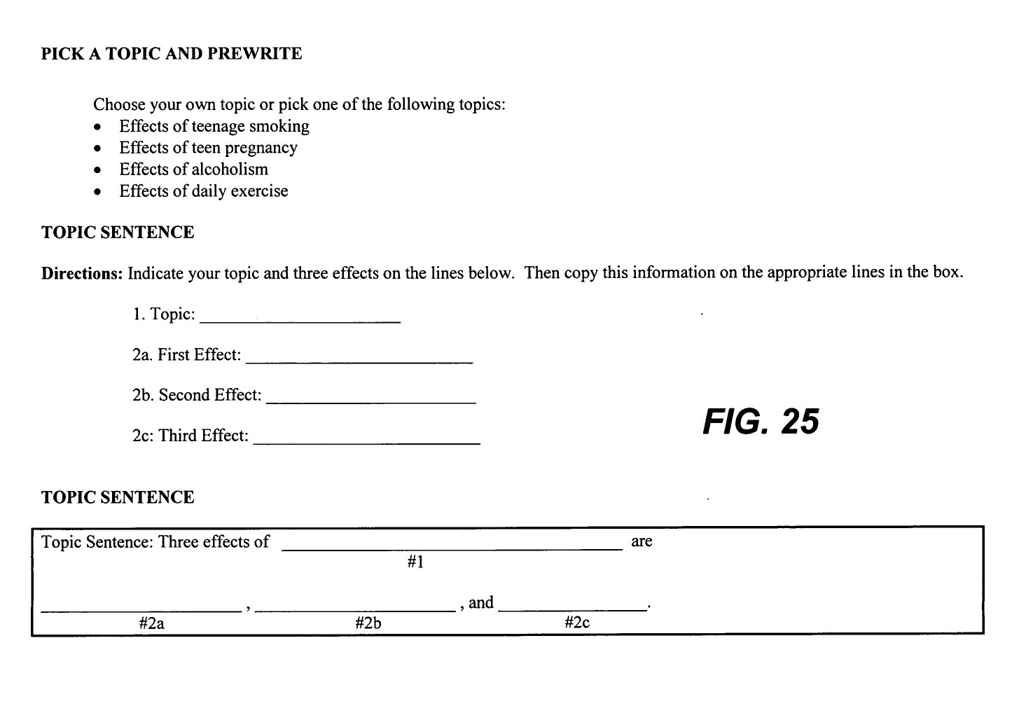

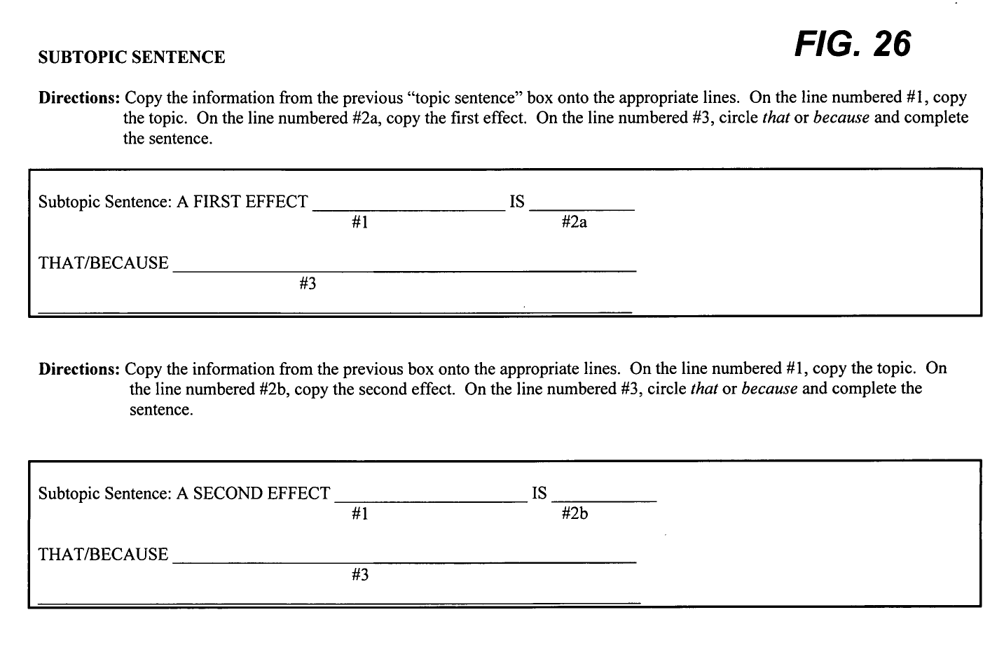

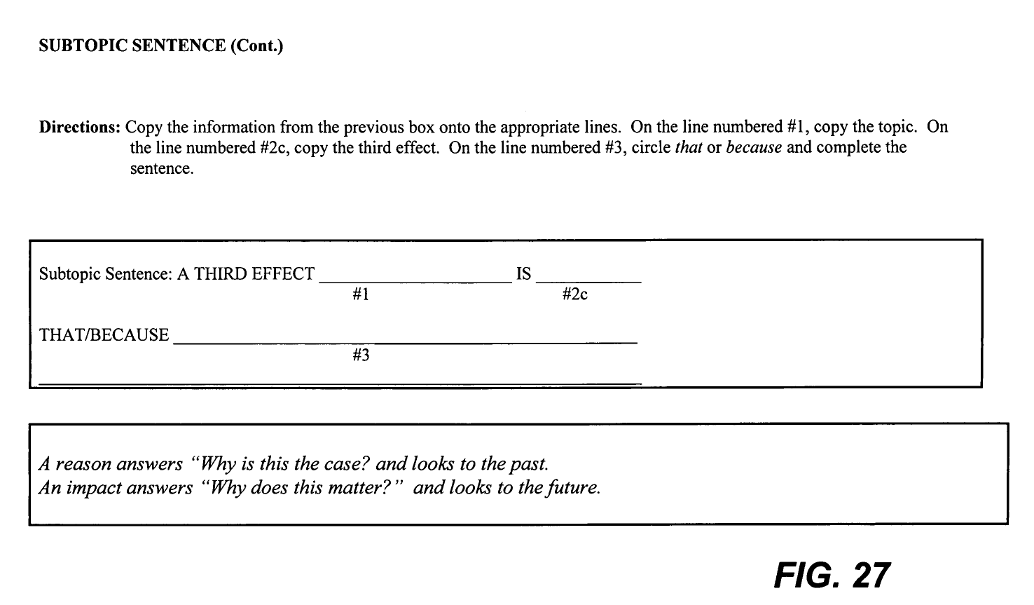

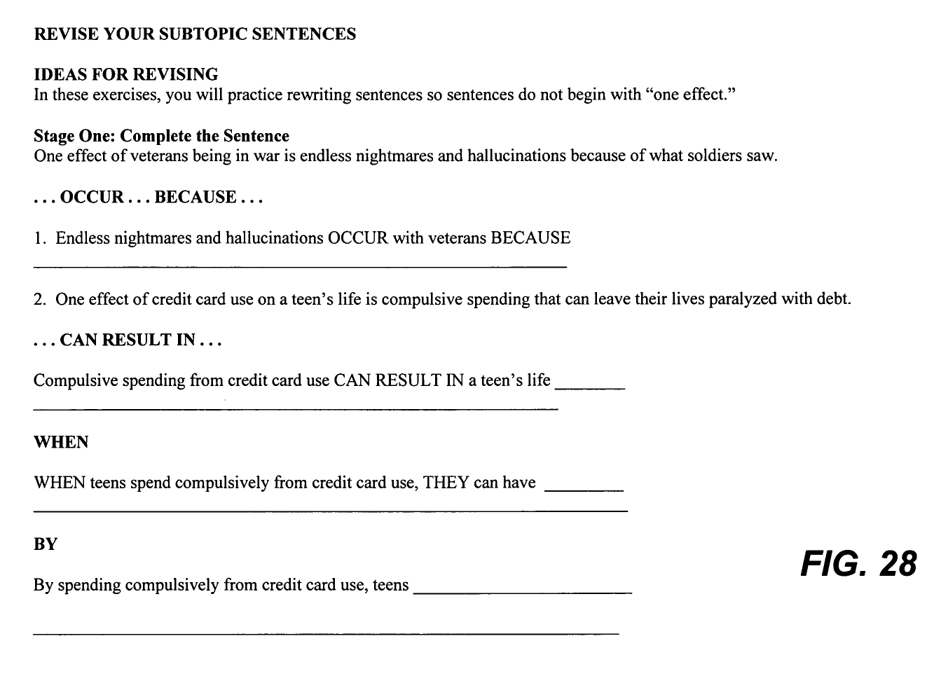

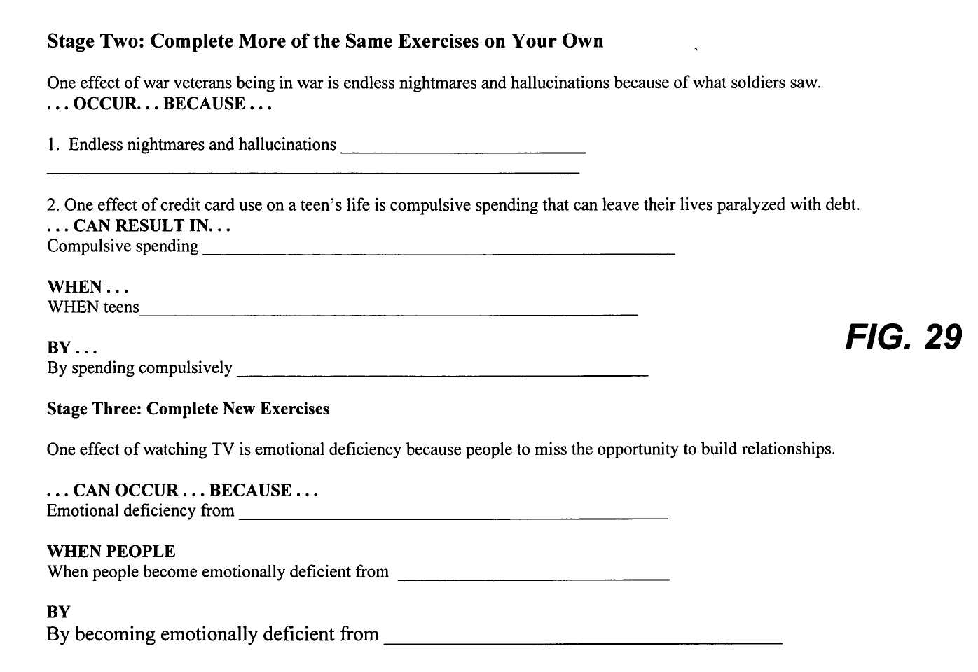

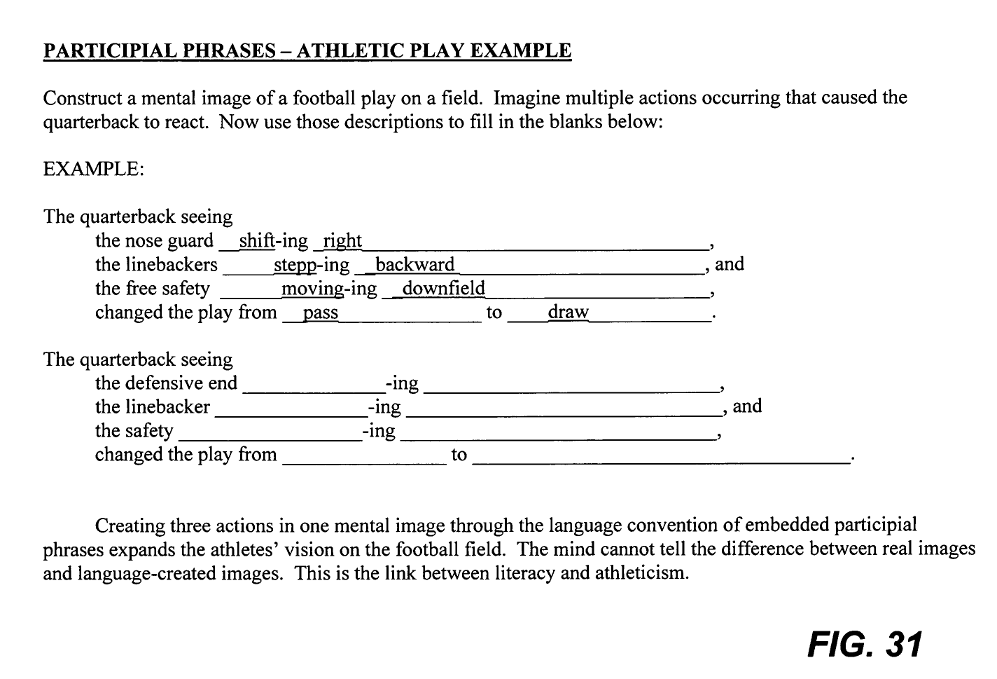

Similar to the above embodiment of invention in regards to FIG. 5, FIGS. 6-31 illustrate alternative embodiments of learning template (100). Different parts of speech, as well as varying semantic and grammatical functional units, can be progressively presented to a tutee to strengthen the tutee's literacy skills, such as the progressive subtopic sentence templates illustratively presented in FIGS. 22-29.

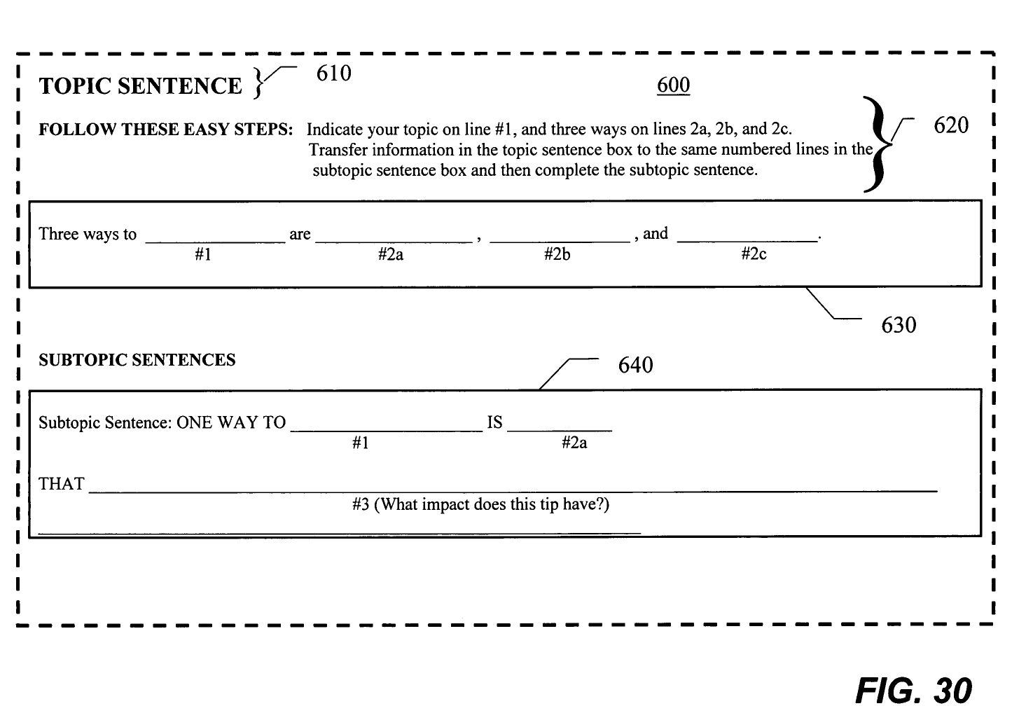

Embodiments of the method of the present invention, such as shown in FIG. 30, provide directions with simple steps to follow that do not require verbal explanations. In one embodiment of a learning template (600), such as for a topic sentence (610), a tutee could be instructed to write by numbers; that is, a tutee is provided simplified “steps to follow” instructions (620) that prompt the tutee to follow guided learning activities by filling in response blanks (630) (640) in a specific order. Without simple instructions (620) and guidance indicia, when students write a topic sentence and then use information in the topic sentence to write subtopic sentences, for example, significant verbal explanation is required. However, using simplified directions (620) with writing by numbers in a fill-in-the-blank approach (630) (640), the learning becomes self-directed and does not require significant verbal reinforcement.

While preferred embodiments of this invention have been shown and described, modifications thereof can be made by one skilled in the art without departing from the spirit or teaching of this invention. The embodiments described herein are exemplary only and are not limiting. Many variations and modifications of the method and any apparatus are possible and are within the scope of the invention. One of ordinary skill in the art will recognize that the process just described may easily have steps added, taken away, or modified without departing from the principles of the present invention. Accordingly, the scope of protection is not limited to the embodiments described herein, but is only limited by the claims that follow, the scope of which shall include all equivalents of the subject matter of the claims.

What is claimed is:

1. A method of coaching literacy comprising:
(a) providing a first learning template for an educational concept to a tutee;
(b) said tutee reading examples of said educational concept presented by said first learning template;
(c) said tutee reading instructions presented by said first learning template;
(d) said tutee completing blanks on said first learning template;
(e) monitoring, by a tutor, said tutee's completions to said blanks on said first learning template;
(f) said tutor providing feedback and substituting correct responses on said first learning template for incorrect responses without providing verbal explanations;
(g) said student reviewing said feedback and said correct responses on said first learning template without listening to verbal explanations;
(h) said tutor determining whether said tutee has mastered said educational concept;
(i) repeating steps (c), (d), (e), (f), (g), and (h) until said tutor has determined that said tutee has achieved sufficient mastery;
(j) presenting said tutee with a second learning template with fewer prompted examples;
(k) said tutee providing input to complete said second learning template;
(l) said tutor monitoring said tutee's completion of said second learning template;
(m) said tutor providing feedback and substituting correct responses for incorrect responses on said second learning template without providing verbal explanations;
(n) said student reviewing said feedback and said correct responses on said second learning template without listening to verbal explanations;
(o) said tutor determining whether said tutee has mastered said educational concept, and;
(p) repeating steps (k), (l), (m), (m), (o), and (p) until said tutor has determined that said tutee has achieved sufficient mastery.

2. The method of claim 1 further comprising said tutor providing an explanation for what the tutee has learned non-verbally.

3. The method of claim 1, further comprising presenting a next educational concept to said tutee, and continuing with step (a).

4. The method of claim 1 further comprising reviewing records relating to said tutee's responses and progress in mastering individual exercises.

5. The method of claim 1 wherein said blanks comprise one or more partial sentence examples.

6. The method of claim 5 wherein said one or more partial sentence examples comprise one or more blank component elements for a part of speech.

7. The method of claim 5 wherein said one or more partial sentence examples comprise one or more blank component elements for adjectives.

8. The method of claim 5 wherein said one or more partial sentence examples comprise one or more blank component elements for sentence subjects.

9. The method of claim 5 wherein said one or more partial sentence examples comprise one or more blank component elements for participial phrases.

10. The method of claim 5 wherein said one or more partial sentence examples comprise one or more blank component elements for verbs.

11. The method of claim 5 wherein said one or more partial sentence examples comprise one or more blank component elements for adverbs.

12. The method of claim 5 wherein said one or more partial sentence examples comprise one or more blank component elements for prepositional phrases.

13. The method of claim 5 wherein said one or more partial sentence examples comprise one or more blank component elements for sentence fragments.

14. The method of claim 5 wherein said one or more partial sentence examples comprise one or more blank component elements for entire sentences.

15. A learning template for enhancing the effectiveness of directed coaching between a tutor and tutee, comprising:
a title corresponding to a learning skill being taught to the tutee;
one or more text examples, whereby said text examples are parsed into component elements, said component elements identified by grammatical function;
one or more directions instructing said tutee in steps to successfully complete said learning template; and
one or more partially complete sentences, whereby said partially complete sentences contain one or more blank component elements, said one or more blank component elements identified by desired grammatical function.

16. The learning template of claim 15 further comprising one or more prepared feedback statements.

17. The learning template of claim 15 further comprising one or more questions to reinforce said tutee's learning experience.

18. The learning template of claim 15 further comprising one or more suggestions for identifying said blank component elements in alternate contexts.

19. The learning template of claim 15 further comprising said one or more text examples arranged in a matrix orientation, whereby said blank component elements appear in columns corresponding to said desired grammatical functions.

20. The learning template in claim 15 further comprising
a steps-to-follow instruction for completing response blanks in a specific order, and;
guidance indicia associated with said response blanks and said steps-to-follow instruction.

21. The learning template in claim 15, wherein said template is presented to said tutee through a computer output device.

22. The learning template of claim 15, wherein said template is stored electronically.

23. The learning template of claim 22, wherein said template is relayed to said tutee through a network.

24. A system for coaching literacy comprising:
(a) means for receiving input;
(b) means for providing output;
(c) means for receiving, storing, and evaluating input from a tutee;
(d) means for storing and retrieving one or more learning templates; and
(e) software means for providing a system for coaching literacy to said tutee, said software stored on a storage medium.

25. The system of claim 25 further comprising means for transmitting said learning templates through a network.
